(19) United States
(12) Patent Application Publication
(10) Pub. No.: US 2026/0136833 A1
(43) Pub. Date: May 14, 2026

(54) OPTOELECTRONIC COMPONENT WITH A PHOTOACTIVE LAYER DESIGNED AS A PLANAR HETEROJUNCTION

(71) Applicant: Heliatek GmbH, Dresden (DE)

(72) Inventors: Ludovic COUTABLE; Andre WEISS

(21) Appl. No.: 18/878,729

(22) PCT Filed: Jun. 30, 2023
(86) PCT No.: PCT/DE2023/100498

§ 371 Date: Dec. 24, 2024

(30) Foreign Application Priority Data
Jun. 30, 2022 (DE) 10 2022 116 403.9

(51) Int. Cl. H10K 85/60; C07F 5/02; H10K 30/30

(52) U.S. Cl. CPC H10K 85/658; C07F 5/027; H10K 85/653; H10K 85/654; H10K 85/655; H10K 85/657; H10K 30/30

(57) ABSTRACT

The invention relates to optoelectronic component, comprising a bottom electrode (2), a top electrode (6), and a layer system (7) with at least one photoactive layer (4). The layer system is arranged between the bottom electrode and the top electrode, and at least one photoactive layer is designed as a planar heterojunction (PHJ), wherein the at least one photoactive layer designed as a planar heterojunction has at least one chemical compound of the general formula I. The invention also relates to the use of such a compound of the general formula I in an optoelectronic component and to a chemical compound of the general formula II.

The present invention relates to an optoelectronic component having at least one photoactive layer in the form of a planar heterojunction (PHJ), wherein the at least one photoactive layer comprises a chemical compound of the general formula I, and to the use of such a compound of the general formula I in an optoelectronic component.

Optoelectronic components may be displays, data storage media or transistors, but also photovoltaic elements, especially solar cells, and photodetectors, which have a photoactive layer in which incidence of electromagnetic radiation generates electron-hole pairs (excitons). The excitons arrive through diffusion at such an interface where electrons and holes are separated from one another. The material that accepts the electrons is referred to as acceptor, and the material that accepts the holes is referred to as donor. Organic optoelectronic components enable the conversion of electromagnetic radiation to electrical current with exploitation of the photoelectric effect. A conversion of electromagnetic radiation of this kind requires absorber materials that show good absorption properties.

Organic optoelectronic components are known from the prior art.

WO2004083958A2 discloses a photoactive component, in particular a solar cell, consisting of organic layers of one or more pi, ni, and/or pin diodes stacked on top of one another.

WO2011161108A1 discloses a construction of an organic solar cell as a pin or nip diode. A pin solar cell consists of a substrate having a usually transparent electrode disposed thereon, p layer(s), i layer(s), n layer(s) and a counterelectrode. In this context, n and p respectively mean n and p doping, which leads to an increase in the density of free electrons/holes at the thermal equilibrium state. Such layers should be understood primarily as transport layers. The term “i layer” refers to an undoped layer (intrinsic layer) having one absorber material or a mixture of two or more absorber materials (planar heterojunction). One or more i layers may consist here of a mixture of two or more materials (bulk heterojunctions), at least one donor and at least one acceptor. What is meant in particular by an absorber material, i.e. an absorber, is a compound that absorbs light in a particular wavelength range. What is meant in particular by an absorber layer is accordingly a layer in an optoelectronic component that comprises at least one absorber material.

The prior art discloses numerous polymeric and nonpolymeric absorber materials for organic photovoltaic elements in the red and near infrared (NIR) region between about 600 and about 1400 nm. In the field of nonpolymeric absorber materials, materials from the substance class of the BODIPYs in particular have been found to be suitable for the near infrared spectral region, which means that suitable energy levels and hence high photovoltages can be achieved with simultaneously long-wave absorption regions.

EP 3 014 674 A1 discloses an organic electronics component comprising at least one organic layer between two electrodes, where the organic layer comprises at least one compound from the group of BODIPYs.

Bartelmess et al. (“meso-Pyridyl BODIPYs with tunable chemical, optical and electrochemical properties”, New Journal of Chemistry, 2013, 37(9), 2663-2668) discloses the synthesis of meso-pyridyl-substituted BODIPY compounds and the optical and electrochemical properties thereof.

The absorbers known from the prior art are not usable in an efficiency sufficient for commercial use in planar heterojunctions of electronic components. The known absorber materials show low efficiency in particular. The efficiency of an organic photovoltaic element depends on factors including the absorption characteristics of the organic materials, i.e. the absorber materials, in the photoactive layer. Although the known absorber materials are suitable for photoactive layers in organic photovoltaic elements, i.e. organic solar cells, there is a need for improvement in the absorption properties of the absorber materials.

A disadvantage, however, is that planar heterojunctions (PHJs) are not of good suitability for use in electronic components, especially of photovoltaic elements, especially since the efficiency of the photovoltaic elements was greatly limited as a result, possibly by a limited exciton diffusion length in such layers. PHJ cells have therefore not been an option to date for industrial use in photovoltaic elements.

However, it would be desirable to use PHJs in photovoltaic elements since the efficiency of photovoltaic elements is improved, and production is simplified. There is a need for absorber materials that have high absorption particularly in the red and near infrared spectral region, and hence lead to high efficiency in a PHJ. In a BHJ, each component must form microdomains that are connected to one another in closed percolation pathways, since no charge transport can otherwise take place. A factor of particular relevance here is the size of the individual microdomains, with excessively large individual domains leading to a loss of photocurrent. Optimal process parameters for production thereof are achievable only with difficulty, and so the industrially achievable efficiency of a BHJ is inferior to the possibilities under idealized laboratory conditions. A PHJ, by contrast, has much lower demands on process parameters since the morphology of individual layers intrinsically has fewer degrees of freedom to be controlled by comparison with a BHJ.

It is therefore the object of the invention to provide an optoelectronic component having at least one photoactive layer in the form of a planar heterojunction that comprises a chemical compound of the general formula I and for use of the chemical compound of the general formula I in a photoactive layer in the form of a planar heterojunction in an optoelectronic component, wherein the disadvantages mentioned do not occur, and wherein the use of planar heterojunctions is possible in particular without limiting the efficiency of the photovoltaic elements.

The object is achieved by the subjects of the independent claims. Advantageous configurations are evident from the dependent claims.

The object is achieved in particular by providing an optoelectronic component, preferably a photovoltaic element, having a base electrode, a top electrode and a layer system having at least one photoactive layer, wherein the layer system is disposed between the base electrode and the top electrode, wherein at least one photoactive layer is formed as a planar heterojunction (PHJ), and wherein the at least one photoactive layer in the form of a planar heterojunction comprises at least one chemical compound of the general formula I

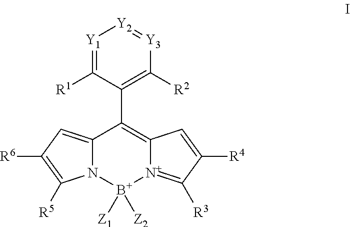

with Y₁ selected from the group consisting of N and CR21, wherein R21 is H, alkyl, O-alkyl, S-alkyl, a halogen, preferably F or Cl, CN, CF₃ or SF₅;
with Y₂ selected from the group consisting of N and CR22, wherein R22 is H, alkyl, O-alkyl, S-alkyl, a halogen, preferably F or Cl, CN, CF₃ or SF₅;
with Y₃ selected from the group consisting of N and CR23, wherein R23 is H, alkyl, O-alkyl, S-alkyl, a halogen, preferably F or Cl, CN, CF₃ or SF₅;
with Z₁ and Z₂ independently selected from the group consisting of F, Cl, CN, CF₃, C₂F₅, OCH₃, and OC₂H₅;
with R1 and R2 independently selected from the group consisting of H, F, Cl, Br, CN, CF₃, CHF₂, CH₂F, C₁-C₄-alkyl, O—C₁-C₄-alkyl, S—C1-C4-alkyl, and N—(C1-C4-alkyl)₂, with the proviso that at least R1 or R2 is Br, Cl, CF₃, CHF₂, CH₂F or CH₃;
with R3 and R5 independently selected from the group consisting of H, halogen, CN, unsubstituted and aryl- or heteroaryl-substituted alkyl, unsubstituted and aryl- or heteroaryl-substituted alkenyl, O-alkyl, S-alkyl, an unsubstituted and alkyl-substituted heterocyclic 5-membered ring and 6-membered ring, preferably having at least one heteroatom selected from S, O and N, and an unsubstituted and alkyl-substituted homocyclic 6-membered ring, wherein the unsubstituted or substituted heterocyclic 5-membered ring or 6-membered ring, or the unsubstituted or substituted homocyclic 6-membered ring may be fused to a further unsubstituted or substituted heterocyclic 5-membered ring or 6-membered ring; with R4 and R6 independently selected from the group consisting of H, halogen, CN, alkyl, alkenyl, O-alkyl, S-alkyl, an unsubstituted and halogen-, alkyl- and/or O-alkyl-substituted heterocyclic 5-membered ring and 6-membered ring, preferably having at least one heteroatom selected from S, O or N, and an unsubstituted and halogen-, alkyl- and/or O-alkyl-substituted homocyclic 6-membered ring;
or wherein R3 and R4 and/or R5 and R6 in each case together form an unsubstituted or halogen-, alkyl-, O-alkyl-, aryl- and/or heteroaryl-substituted heterocyclic 5-membered ring or 6-membered ring, preferably having at least one heteroatom selected from S, O and N, or an unsubstituted or halogen-, alkyl-, O-alkyl-, aryl- and/or heteroaryl-substituted homocyclic 6-membered ring.

What is meant in particular by substitution is the exchange of H by a substituent. What is meant in particular by a substituent is any atoms and atomic groups except hydrogen, preferably a halogen, preferably F, Cl or Br, more preferably F, an alkyl group, wherein the alkyl group may be linear or branched, an alkenyl group, an alkynyl group, an amino group, an alkoxy group, a thioalkoxy group, an aryl group, or a heteroaryl group.

What is meant in particular by a heteroatom, in particular a heteroatom in the general formula I, is an atom selected from the group consisting of O, S, Se and N.

In a preferred embodiment of the invention, Y1 is selected from the group consisting of N and CR21, wherein R21 is H, C1-C4-alkyl, or a halogen, preferably F or Cl; Y2 is selected from the group consisting of N and CR22, wherein R22 is H, alkyl, O-alkyl, S-alkyl, a halogen, preferably F or Cl, CN, CF3 or SF5; and Y3 is selected from the group consisting of N and CR23, wherein R23 is H, C1-C4-alkyl, or a halogen, preferably F or Cl.

In a preferred embodiment of the invention, R1 and R2 are independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl or CF₃.

In a preferred embodiment of the invention, in the substituted alkenyl, O-alkyl or S-alkyl in R3 and R5, a hydrogen atom is replaced by a group selected from an unsubstituted and substituted heterocyclic 5-membered ring or 6-membered ring, preferably having at least one heteroatom selected from S, O and N, and an unsubstituted and substituted homocyclic 6-membered ring.

In a preferred embodiment of the invention, in R3 and/or R5, the unsubstituted or substituted heterocyclic 5-membered ring or 6-membered ring, or the unsubstituted or substituted homocyclic 6-membered ring, are further fused to at least one further heterocyclic 5-membered ring or 6-membered ring or to at least one homocyclic 6-membered ring, preferably to an unsubstituted or substituted heterocyclic 5-membered ring having at least one heteroatom selected from S and O.

In a preferred embodiment of the invention, R3 and R4 and/or R5 and R6 in each case together form an unsubstituted or a halogen-, alkyl-, O-alkyl-, aryl- and/or heteroaryl-substituted heterocyclic 5-membered ring or 6-membered ring, preferably having at least one heteroatom selected from S, O and N, or an unsubstituted or a halogen-, alkyl-, O-alkyl-, aryl- and/or heteroaryl-substituted homocyclic 6-membered ring.

In a preferred embodiment of the invention, the unsubstituted or substituted heterocyclic 5-membered ring or 6-membered ring formed between R3 and R4 and/or R5 and R6, or the unsubstituted or substituted homocyclic 6-membered ring, are not further fused.

In a preferred embodiment of the invention, R4 and R6 are independently selected from the group consisting of H, halogen, CN, and unsubstituted and substituted alkyl. In a particularly preferred embodiment, R4 and R6 are H.

In a preferred embodiment of the invention, R4 and R6 are the same, and/or R3 and R5 are the same.

In a preferred embodiment of the invention, Z1 is the same as Z2, R3 is the same as R5, and R4 is the same as R6.

What is meant in particular by an optoelectronic component is a photovoltaic element having at least one organic photoactive layer, wherein the organic photoactive layer comprising at least one compound of the invention. An organic photovoltaic element allows electromagnetic radiation, particularly in the visible light wavelength range, to be converted to electrical current with exploitation of the photoelectric effect. In this context, the term “photoactive” means the conversion of light energy to electrical energy. By contrast with inorganic solar cells, in the case of organic photovoltaic elements, rather than direct creation of free charge carriers by the light, excitons are first formed, i.e. electrically neutral excitation states (bound electron-hole pairs). Only in a second step are these excitons separated at a photoactive donor-acceptor junction into free charge carriers, which then contribute to the flow of electrical current.

The optoelectronic component of the invention has advantages by comparison with the prior art. Advantageously, it is possible to provide improved absorbers for planar heterojunctions in optoelectronic components. Because of the limited diffusion length in planar heterojunctions that limits efficiency of the optoelectronic components based on planar heterojunctions, the use of planar heterojunctions was to date possible only with difficulty. However, the use of planar heterojunctions in optoelectronic components is desirable by comparison with bulk heterojunctions because of easier producibility. Advantageously, the compounds of the invention enable an improved EQEₘₐₓ (maximum external quantum yield) in optoelectronic components having planar heterojunctions. Advantageously, the compounds of the invention enable the use of planar heterojunctions in commercial optoelectronic components that are in particular more easily producible compared to bulk heterojunctions. Advantageously, absorber materials for the red and near infrared spectral region having high absorption intensity and particularly good evaporability are provided for planar heterojunctions as well, which are especially processible under reduced pressure without degradation. Advantageously, the steric configuration of the groups in the meso position of the BODIPY base skeleton in particular leads to a preferred spatial arrangement of the compounds in the photoactive layer. The effect of an improved PHJ cell appears to result from an increased exciton diffusion length. Advantageously, the compounds of the invention show unusually good properties in a planar heterojunction (PHJ), in particular enabling higher layer thicknesses and consequently higher efficiencies of solar cells.

In a preferred embodiment of the invention, Z₁ and Z₂ are each F or CF₃.

In a particularly preferred embodiment of the invention, in R1 and R2, C1-C4-alkyl, O—C1-C4-alkyl, S—C1-C4-alkyl and N—(C1-C4-alkyl)₂ are substituted, preferably by a substituent selected from the group consisting of: F, Cl, CN, CF3 and COR8, wherein R8 is C1-C4-alkyl.

In one development of the invention, it is provided that Z₁ and Z₂ are F; and/or R1 and R2 are independently selected from the group consisting of H, F, Br, Cl, CN, Me, Et, OMe, SMe, OEt, SEt, Pr and iPr, with the proviso that at least R1 or R2 is Br, Cl or CF₃, wherein preferably R1 and R2 are not H; or R1 and R2 are independently selected from the group consisting of Cl, Br, CF₃, CN, Me, Et, OMe, SMe, OEt and SEt, with the proviso that at least R1 or R2 is Cl, Br, CF₃ or Me; or preferably R1 and R2 are selected from the group consisting of Br, Cl, CF₃, CHF₂, CH₂F and CH₃.

In a particularly preferred embodiment of the invention, R1 and R2 are independently selected from the group consisting of Cl, CN, Me, Et, OMe, SMe, OEt and SEt, with the proviso that at least R1 or R2 is Cl.

In one development of the invention, it is provided that Y₁ is selected from the group consisting of N and CR21, wherein R21 is H or Cl, and/or Y₂ is selected from the group consisting of N and CR22, wherein R22 is H, CH₃, O—CH₃, S—CH₃, F, Cl, CF₃ or SF₅, preferably N or CH, and/or Y₃ is selected from the group consisting of N and CR23, wherein R23 is H or Cl; wherein preferably one Y₁, Y₂, Y₃ is an N, or two Y₁, Y₂, Y₃ are an N.

In a preferred embodiment of the invention, Y₁ is N or CH, and/or Y₂ is N, CH or C-halogen, preferably C—F or C—Cl, and/or Y₃ is N and CH, wherein preferably at least one Y₁, Y₂, Y₃ is an N, or at least two Y₁, Y₂, Y₃ are an N.

In a preferred embodiment of the invention, Y₁ is N, Y₂ is CH, and Y₃ is N, or Y₁ is N, Y₂ is C-halogen, preferably C—F or C—Cl, and Y₃ is N, or Y₁ is CH, Y₂ is N, and Y₃ is CH, or Y₁ is CH, Y₂ is CH, and Y₃ is CH, and/or Y₁ is CH, Y₂ is C-halogen, preferably C—F or C—Cl, and Y₃ is CH.

In one development of the invention, it is provided that R3 and R4 and/or R5 and R6 form an unsubstituted or substituted heterocyclic 5-membered ring or 6-membered ring having at least one heteroatom selected from O, S and N, preferably from O and S, or an unsubstituted or substituted homocyclic 6-membered ring, or R3 and R4 and/or R5 and R6 form an unsubstituted or substituted heterocyclic 5-membered ring, preferably a substituted heterocyclic 5-membered ring, having at least one heteroatom selected from O, S and N, preferably O and S, or an unsubstituted or substituted homocyclic 6-membered ring, preferably an unsubstituted homocyclic 6-membered ring.

In a preferred embodiment of the invention, the respectively substituted heterocyclic 5-membered ring or 6-membered ring formed between R3 and R4 and/or R5 and R6, preferably having at least one heteroatom selected from S, O and N, is substituted selected from the group consisting of halogen, CN, alkyl, O-alkyl, S-alkyl, an unsubstituted and substituted heterocyclic 5-membered ring or 6-membered ring, preferably having a heteroatom independently selected from S, O and N, and an unsubstituted and substituted homocyclic 6-membered ring. In a preferred embodiment of the invention, the homocyclic 6-membered ring is unsubstituted.

In a preferred embodiment of the invention, the respectively substituted homocyclic 6-membered ring formed between R3 and R4 and/or R5 and R6 is substituted selected from the group consisting of halogen, CN, alkyl, O-alkyl, S-alkyl, an unsubstituted and substituted heterocyclic 5-membered ring or 6-membered ring, preferably having a heteroatom independently selected from S, O and N, and an unsubstituted and substituted homocyclic 6-membered ring. In a preferred embodiment of the invention, the homocyclic 6-membered ring is unsubstituted.

In a preferred embodiment of the invention, R3 and R4 and/or R5 and R6 in each case together form an unsubstituted or substituted heterocyclic 5-membered ring or 6-membered ring having at least one heteroatom selected from S, O and N. In a preferred embodiment of the invention, R3 and R4 and/or R5 and R6 in each case together form an unsubstituted or substituted furanyl ring or thienyl ring.

In a preferred embodiment of the invention, the unsubstituted or substituted heterocyclic 5-membered ring or 6-membered ring formed by R3 and R4 and/or R5 and R6, or the unsubstituted or substituted homocyclic 6-membered ring, is fused to an unsubstituted or substituted thienyl ring or furanyl ring.

In a preferred embodiment of the invention, R3 and R4 and/or R5 and R6 in each case together form an unsubstituted heterocyclic 5-membered ring or 6-membered ring, preferably having at least one heteroatom selected from S, O and N.

In a preferred embodiment of the invention, R3 and R4 and/or R5 and R6 in each case together form an unsubstituted or substituted homocyclic 6-membered ring, and R3 and R4 and/or R5 and R6 in each case together do not form a heterocyclic 5-membered ring or 6-membered ring.

In one development of the invention, it is provided that the at least one chemical compound is a compound of the general formula II

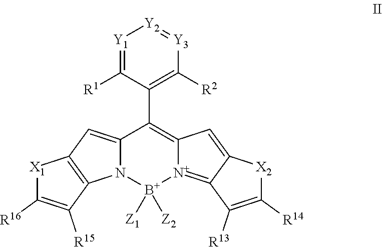

with Y₁ selected from the group consisting of N and CR21, wherein R21 is H, alkyl, preferably C1-C4-alkyl, O-alkyl, S-alkyl, or a halogen, preferably F or Cl;
with Y₂ selected from the group consisting of N and CR22, wherein R22 is H, alkyl, preferably C1-C4-alkyl, O-alkyl, S-alkyl, a halogen, preferably F or Cl, CN or CF₃;
with Y₃ selected from the group consisting of N and CR23, wherein R23 is H, alkyl, preferably C1-C4-alkyl, O-alkyl, S-alkyl, or a halogen, preferably F or Cl;
with Z₁ and Z₂ F or CF₃;
with X₁ and X₂ independently O, S or N—R8 with R8 selected from the group consisting of H, alkyl and aryl, wherein preferably X₁ and X₂ are S or X₁ and X₂ are O;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CHF₂, CH₂F or CH₃, preferably Br or Cl;
wherein R13 and R15 are independently selected from the group consisting of H, halogen, CN, alkyl, O-alkyl and S-alkyl, preferably H or Cl-C4-alkyl;
wherein R14 and R16 are independently selected from the group consisting of an unsubstituted and halogen-, alkyl-, fluorinated alkyl-, O-alkyl- and/or fluorinated O-alkyl-substituted heterocyclic 5-membered ring or 6-membered ring, preferably having a heteroatom independently selected from S, O and N, and an unsubstituted and halogen-, alkyl-, fluorinated alkyl-, O-alkyl- and/or fluorinated O-alkyl-substituted homocyclic 6-membered ring, preferably from an unsubstituted and substituted heterocyclic 5-membered ring, and an unsubstituted and substituted homocyclic 6-membered ring.

In a preferred embodiment of the invention, R14 and R16 are a substituted heterocyclic 5-membered ring, wherein at least one hydrogen atom, preferably one hydrogen atom, in the heterocyclic 5-membered ring is substituted, preferably by a substituent selected from the group consisting of H, halogen, CN, alkyl, O-alkyl, and S-alkyl. In a preferred embodiment of the invention, R14 and/or R16 are not further fused.

In a preferred embodiment of the invention, R14 and R16 are independently an unsubstituted or substituted furanyl ring or thienyl ring.

In a preferred embodiment of the invention, X1 and X2 are S or X1 and X2 are O; especially preferably, X₁ and X₂ are O.

In a preferred embodiment of the invention, in R14 and R16 at least one hydrogen atom of the homocyclic 6-membered ring and/or of the heterocyclic 5-membered ring or 6-membered ring is substituted by F or CF3, preferably by F.

In a preferred embodiment of the invention, R13 and R15 are H.

In a preferred embodiment of the invention, R13 and R15 are the same, and/or R14 and R16 are the same.

In a preferred embodiment of the invention, Z1 is the same as Z2, R13 is the same as R15, and R14 is the same as R16.

In a preferred embodiment of the invention, X1 and X2 are O or S, R13 and R15 are H, and R14 and R16 are an unsubstituted or substituted heterocyclic 5-membered ring or 6-membered ring, preferably having a heteroatom selected from S, O and N, or an unsubstituted or substituted homocyclic 6-membered ring, preferably a substituted heterocyclic 5-membered ring.

In a preferred embodiment of the invention, R13 and R14 and/or R15 and R16 in each case form an unsubstituted or substituted heterocyclic 5-membered ring or 6-membered ring having at least one heteroatom selected from S, O and N, or an unsubstituted or substituted homocyclic 6-membered ring.

In a preferred embodiment of the invention, R13 and R14 and/or R15 and R16 in each case form an unsubstituted or substituted heterocyclic 5-membered ring having at least one heteroatom selected from S, O and N.

In a preferred embodiment of the invention, the compounds of the invention do not have a ring structure between R13 and R14 and/or between R15 and R16.

In a development of the invention, it is provided that R14 and R16 are independently selected from the group consisting of

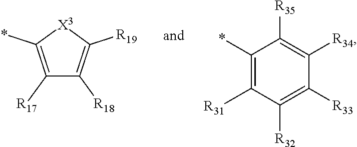

with X₃ O, S, or N—R9 with R9 selected from the group consisting of H, alkyl and aryl;
with R17 to R19 and R31 to R35 independently selected from the group consisting of H, halogen, preferably F and Cl, CN, alkyl, preferably C1-C4-alkyl, O-alkyl, preferably O—C1-C4-alkyl, and S-alkyl, preferably S—C1-C4-alkyl, where preferably at least one hydrogen atom in R31 to R35 is substituted by F.

In a preferred embodiment of the invention, R17 and/or R18 are H, preferably R17 and R18.

In a preferred embodiment of the invention, at least R31 and R35 are H.

In a preferred embodiment of the invention, R31, R32, R34 and R35 are H.

In a further preferred embodiment, R31 to R35 are H.

In one development of the invention, it is provided that Z₁ and Z₂ are F, and R1 and R2 are independently selected from the group consisting of H, F, Cl, Br, CF₃, CHF₂, CH₂F and CH₃, with the proviso that at least R1 or R2 is Br, Cl or CF₃, preferably Br or Cl.

In one development of the invention, it is provided that Y₁ and Y₃ are CH and Y₂ is CR22, preferably with CR22 selected from the group consisting of F, Br, Cl, and CN, or Y₁ is CR21, Y₂ is N and Y₃ is CR23, preferably CR21 and CR23 are H or methyl, or Y₁ is N, Y₂ is CR22 and Y₃ is N, preferably CR22 is H or methyl.

In a preferred embodiment of the invention, R1 and R2 are each F or Cl.

In one development of the invention, it is provided that the at least one chemical compound is a compound of the general formula III

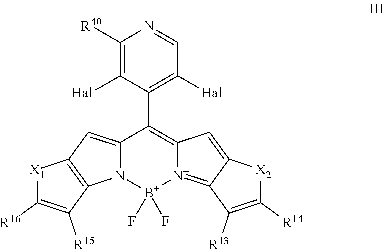

wherein X₁ and X₂ are independently O or S, wherein R⁴⁰ is H, Cl or F, preferably H, and where Hal is F, Br or Cl. In a particularly preferred embodiment of the invention, the meso substituent on the BODIPY base skeleton is (4)-3,5-dichloropyridine, i.e. with each Hal=Cl, and R40=H.

In one development of the invention, it is provided that the at least one chemical compound is a compound of the general formula IV

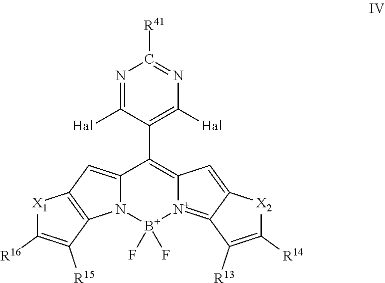

wherein X₁ and X₂ are independently O or S, wherein R⁴¹ is H, F, Cl, Br, CF₃ or C1-C4-alkyl, preferably H, especially preferably H, F or Cl, and wherein Hal is Br, Cl or F.

In one development of the invention, it is provided that the at least one chemical compound is a compound of the general formula V

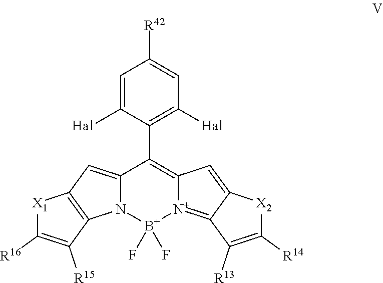

wherein X₁ and X₂ are independently O or S, wherein R⁴² is H, F, Cl, CF₃ or C1-C4-alkyl, and wherein Hal is Br, Cl or F.

In a preferred embodiment of the invention, the at least one chemical compound is a compound of the general formula III, a compound of the general formula VI, and a compound of the general formula III.

In one development of the invention, it is provided that R¹⁴ and R¹⁶ are independently an unsubstituted or halogen-, alkyl- and/or O-alkyl-substituted heterocyclic 5-membered ring having at least one heteroatom selected from S, O and N, preferably O and S, wherein preferably R19, R17 and R19, or R18 and R19 are substituted, or an unsubstituted or a halogen-, alkyl-, fluorinated alkyl-, O-alkyl- and/or fluorinated O-alkyl-substituted homocyclic 6-membered ring, wherein preferably R32, R33, or R32 and R34 are substituted, or R31 to R35 are H.

In one development of the invention, it is provided that the compound is selected from the group consisting of:

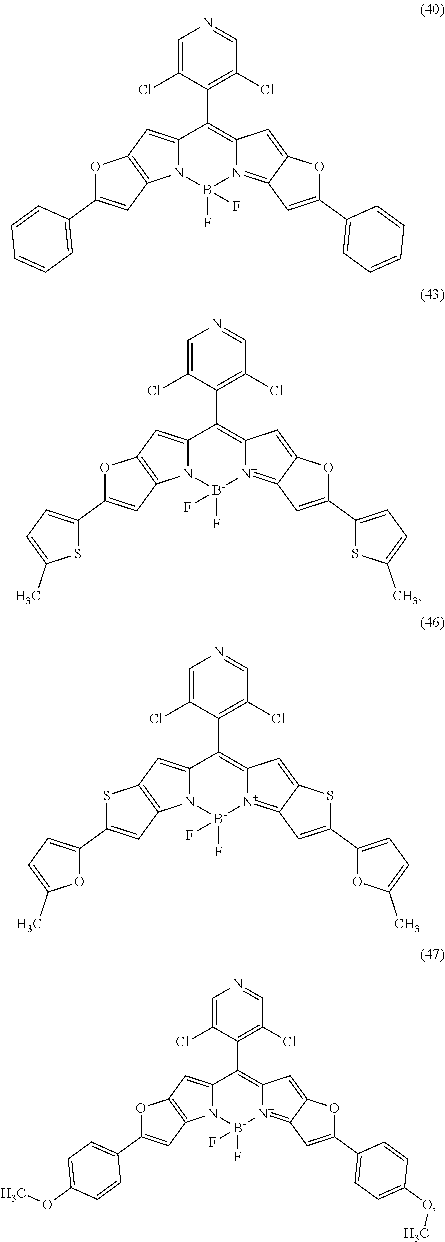

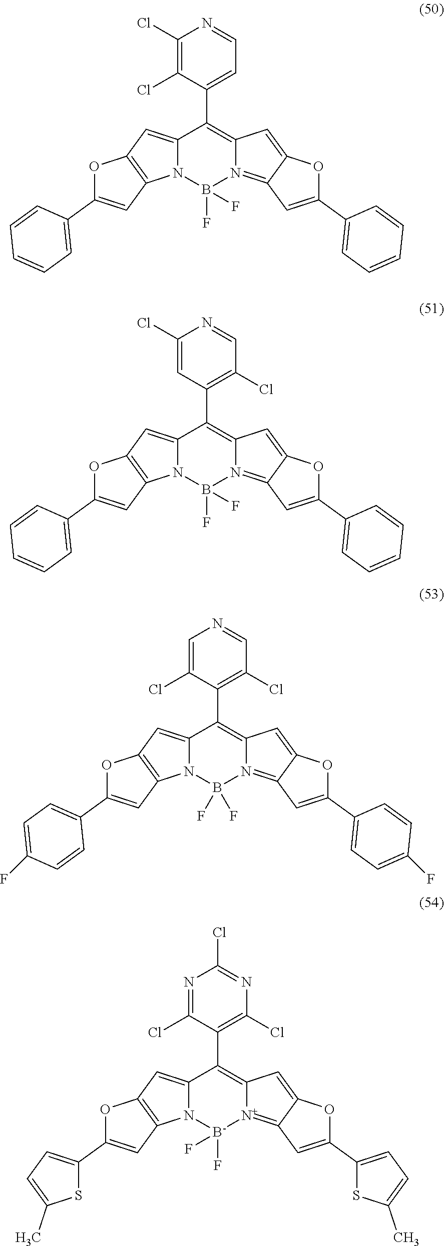

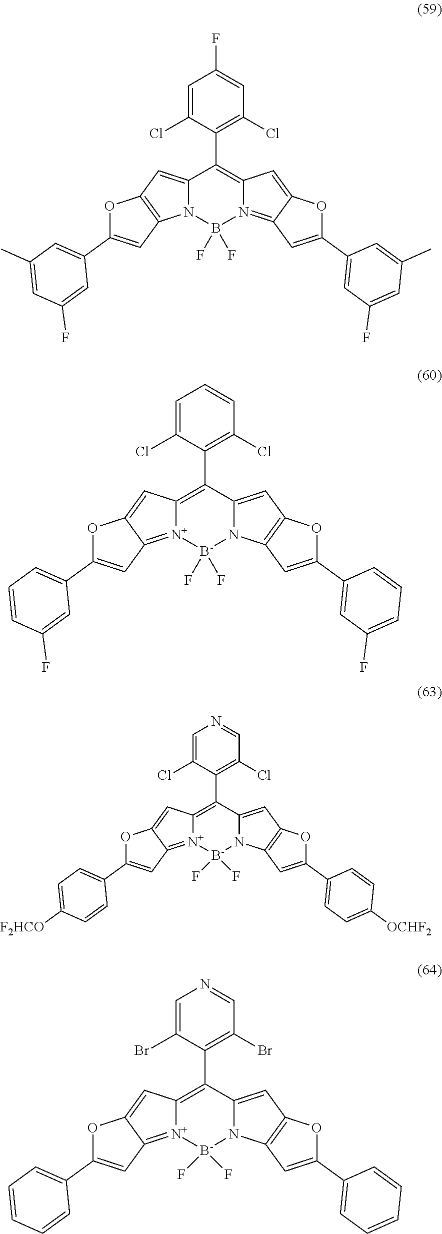

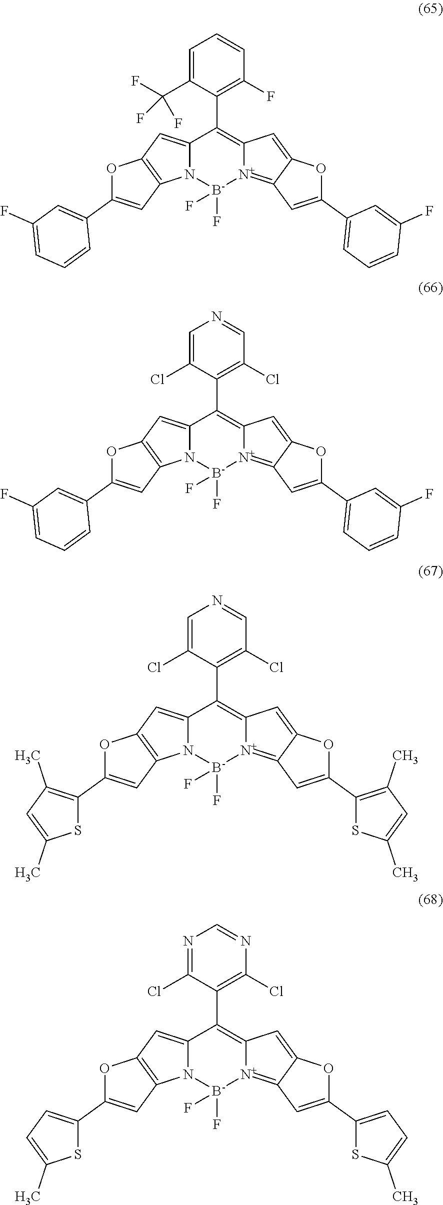 [SMILES: Fc1cccc(-c2cc3c(o2)=CC2=C(c4c(F)cccc4C(F)(F)F)c4cc5oc(-c6cccc(F)c6)cc5n4[B-](F)(F)[N+]=32)c1 ; Fc1cccc(-c2cc3c(o2)=CC2=C(c4c(Cl)cncc4Cl)c4cc5oc(-c6cccc(F)c6)cc5n4[B-](F)(F)[N+]=32)c1 ; Cc1cc(C)c(-c2cc3c(o2)=CC2=C(c4c(Cl)cncc4Cl)c4cc5oc(-c6sc(C)cc6C)cc5n4[B-](F)(F)[N+]=32)s1 ; Cc1ccc(-c2cc3c(o2)=CC2=C(c4c(Cl)ncnc4Cl)c4cc5oc(-c6ccc(C)s6)cc5n4[B-](F)(F)[N+]=32)s1]

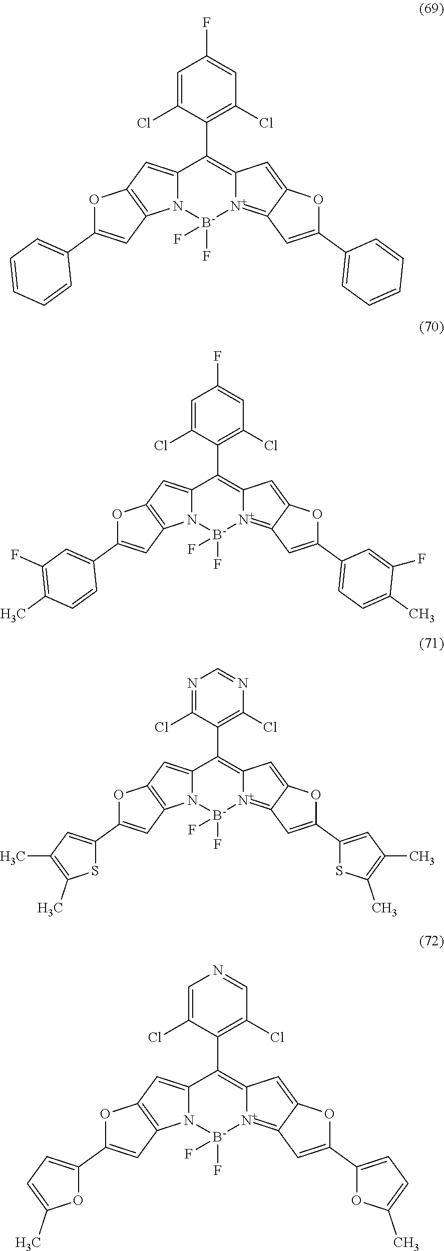

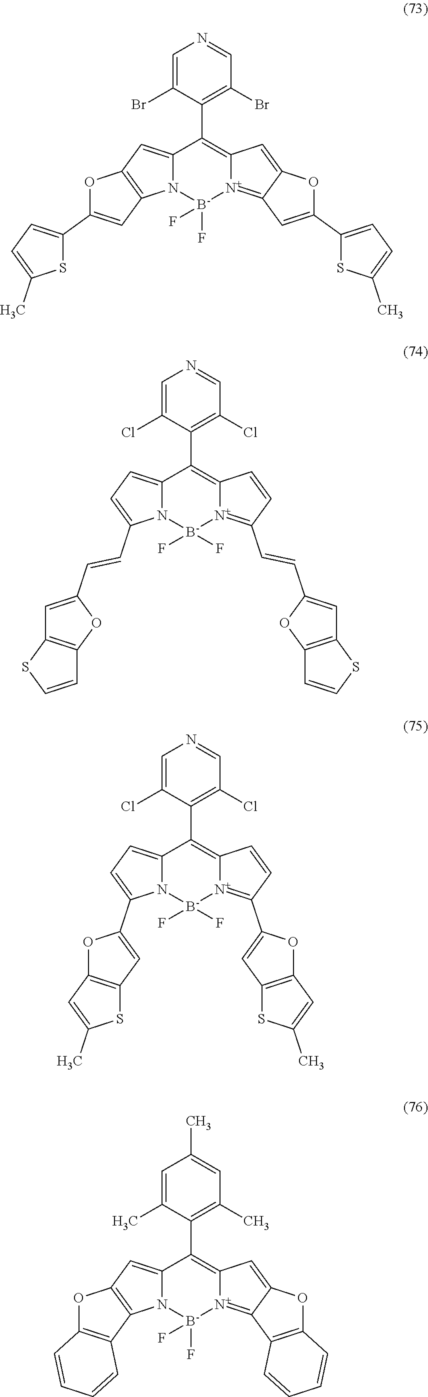 [SMILES: Cc1ccc(-c2cc3c(o2)=CC2=C(c4c(Br)cncc4Br)c4cc5oc(-c6ccc(C)s6)cc5n4[B-](F)(F)[N+]=32)s1 ; F[B-]1(F)n2c(/C=C/c3cc4sccc4o3)ccc2C(c2c(Cl)cncc2Cl)=C2C=CC(/C=C/c3cc4sccc4o3)=[N+]21 ; Cc1cc2oc(C3=[N+]4C(=C(c5c(Cl)cncc5Cl)c5ccc(-c6cc7sc(C)cc7o6)n5[B-]4(F)F)C=C3)cc2s1 ; Cc1cc(C)c(C2=C3C=c4oc5ccccc5c4=[N+]3[B-](F)(F)n3c2cc2oc4ccccc4c23)c(C)c1]

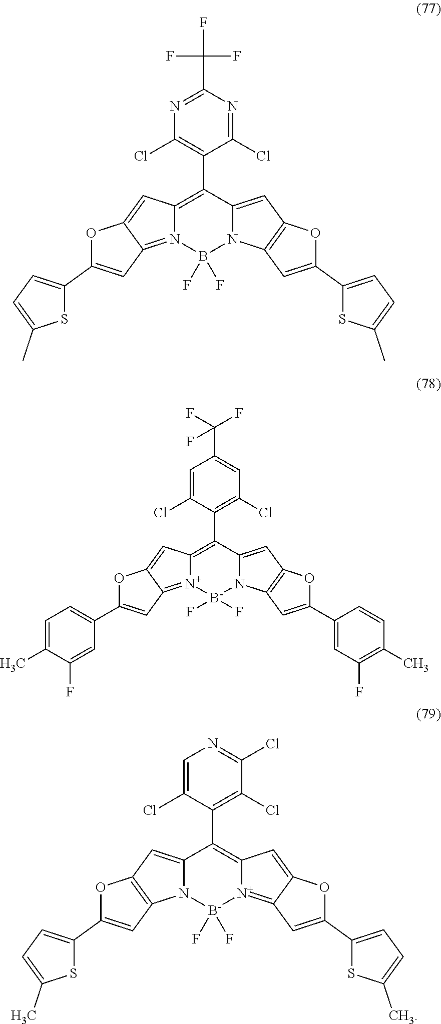

In a preferred embodiment of the invention, the compound is in mirror-symmetric form with respect to the axis through B and the meso position is formed.

A general synthesis for preparation of compounds of the invention having a BODIPY base skeleton and a 4-pyridyl meso group is known from Bartellmess et al. (“meso-Pyridyl BODIPYs with tunable chemical, optical and electrochemical properties”, New Journal of Chemistry, 37(9), 2663-2668; 2013).

The compounds of the invention relate in particular to “small molecules”. What is meant in particular by small molecules is non-polymeric organic molecules having monodisperse molar masses between 100 and 2000 g/mol that are in the solid phase at standard pressure (air pressure of the ambient atmosphere) and at room temperature. In particular, the small molecules are photoactive, wherein photoactive means that the molecules undergo a change of their charge state and/or of their polarization state when exposed to light. A particular feature of the photoactive molecules is an absorption of electromagnetic radiation in a defined wavelength range, with conversion of absorbed electromagnetic radiation, i.e. photons, to excitons.

In one development of the invention, it is provided that the optoelectronic component is an organic optoelectronic component, preferably an organic photovoltaic element, an OFET, an OLED or an organic photodetector, especially preferably an organic photovoltaic element.

In a preferred embodiment of the invention, the at least one photoactive layer is an absorber layer, preferably the at least one compound is an absorber material.

The at least one photoactive layer in the form of a planar heterojunction (PHJ) has a donor layer comprising the at least one compound of the invention as a donor and an acceptor layer disposed thereon, preferably disposed directly thereon, and comprising at least one acceptor; preferably, the acceptor is a fullerene, especially preferably C60, or a fullerene derivative. The acceptor may alternatively be a non-fullerene acceptor (NFA).

In an alternative embodiment of the invention, the at least one photoactive layer in the form of a planar heterojunction (PHJ) has an acceptor layer comprising the at least one compound of the invention as acceptor.

In a preferred embodiment of the invention, the donor layer of the PHJ cell has a layer thickness of 5 nm to 50 nm, preferably of 5 to 20 nm, preferably of 7 to 15 nm.

In a preferred embodiment of the invention, the acceptor layer of the PHJ cell has a layer thickness of 5 nm to 50 nm, preferably of 7 to 15 nm, preferably of 5 to 20 nm.

In a preferred embodiment of the invention, the layer system of the optoelectronic component has at least two photoactive layers, preferably at least three photoactive layers, or preferably at least four photoactive layers.

In a preferred embodiment of the invention, the compound and/or a layer comprising the at least one compound has been deposited by means of gas phase deposition or solvent processing, more preferably by means of vacuum processing.

The object of the present invention is also achieved by providing for use of at least one compound of the invention in a photoactive layer formed as a planar heterojunction (PHJ) in an optoelectronic component, preferably of an organic optoelectronic component, especially according to one of the working examples described above. The use of the at least one compound in the optoelectronic component gives rise in particular to the advantages that have already been elucidated in connection with the optoelectronic component of the invention comprising the at least one compound.

In one development of the invention, it is provided that the compound of the invention is used in an organic optoelectronic component, preferably an organic photovoltaic element, an OLED, an OFET, or an organic photodetector.

In a preferred embodiment of the invention, the at least one compound of the invention is used as absorber material in a photoactive layer of the optoelectronic component. In a preferred embodiment of the invention, the compound of the invention is used as donor in a donor-acceptor heterojunction.

In a preferred embodiment of the invention, the optoelectronic component comprises a substrate, wherein the first electrode or the second electrode is disposed on the substrate; in particular, one of the electrodes of the optoelectronic component may have been applied directly to the substrate, wherein the layer system is disposed between the first electrode and the second electrode.

The object of the present invention is also achieved by providing a chemical compound of the general formula II, especially according to one of the working examples described above. For the chemical compound of the general formula II, this gives rise in particular to the advantages that have already been elucidated in connection with the optoelectronic component of the invention.

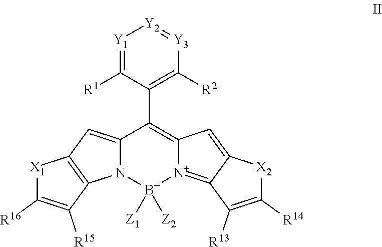

with Y₁ selected from the group consisting of N and CR21, wherein R21 is H, alkyl, O-alkyl, S-alkyl, a halogen, preferably F or Cl, CN or CF₃;
with Y₂ selected from the group consisting of N and CR22, wherein R22 is H, alkyl, O-alkyl, S-alkyl, a halogen, preferably F or Cl, CN or CF₃;
with Y₃ selected from the group consisting of N and CR23, wherein R23 is H, alkyl, O-alkyl, S-alkyl, a halogen, preferably F or Cl, CN or CF₃;
with Z₁ and Z₂ F or CF₃;
with X₁ and X₂ independently O, S or N—R8 with R8 selected from the group consisting of H, alkyl and aryl, wherein preferably X₁ and X₂ are S or X₁ and X₂ are O;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CHF₂, CH₂F or CH₃;
wherein R13 and R15 are independently selected from the group consisting of H, halogen, CN, alkyl, O-alkyl and S-alkyl, preferably H or Cl-C4-alkyl;
wherein R14 and R16 are independently selected from the group consisting of an unsubstituted and halogen-, alkyl-, fluorinated alkyl-, O-alkyl- and/or fluorinated O-alkyl-substituted heterocyclic 5-membered ring or 6-membered ring, preferably having a heteroatom independently selected from S, O and N, and an unsubstituted and halogen-, alkyl-, fluorinated alkyl-, O-alkyl- and/or fluorinated O-alkyl-substituted homocyclic 6-membered ring, preferably from an unsubstituted and substituted heterocyclic 5-membered ring, and an unsubstituted and substituted homocyclic 6-membered ring.

In a preferred embodiment of the invention, in the chemical compound of the general formula II R14 and R16 are a substituted heterocyclic 5-membered ring, wherein at least one hydrogen atom, preferably one hydrogen atom, in the heterocyclic 5-membered ring is substituted, preferably by a substituent selected from the group consisting of H, halogen, CN, alkyl, O-alkyl, and S-alkyl. In a preferred embodiment of the invention, R14 and/or R16 are not further fused.

In a preferred embodiment of the invention, in the chemical compound of the general formula II, X1 and X2 are S or X1 and X2 are O, more preferably X₁ and X₂ are O.

In a preferred embodiment of the invention, in the chemical compound of the general formula II in R14 and R16 at least one hydrogen atom of the homocyclic 6-membered ring and/or of the heterocyclic 5-membered ring or 6-membered ring is substituted by F or CF3, preferably by F.

In a preferred embodiment of the invention, in the chemical compound of the general formula II R13 and R15 are H.

In a preferred embodiment of the invention, in the chemical compound of the general formula II R13 and R15 are the same, and/or R14 and R16 are the same.

In a preferred embodiment of the invention, in the chemical compound of the general formula II Z1 is the same as Z2, R13 is the same as R15, and R14 is the same as R16.

In a preferred embodiment of the invention, in the chemical compound of the general formula II X1 and X2 are O or S, R13 and R15 are H, and R14 and R16 are an unsubstituted or substituted heterocyclic 5-membered ring or 6-membered ring, preferably having a heteroatom selected from S, O and N, or an unsubstituted or substituted homocyclic 6-membered ring, preferably a substituted heterocyclic 5-membered ring.

In a preferred embodiment of the invention, in the chemical compound of the general formula II R13 and R14 and/or R15 and R16 in each case form an unsubstituted or substituted heterocyclic 5-membered ring or 6-membered ring having at least one heteroatom selected from S, O and N, or an unsubstituted or substituted homocyclic 6-membered ring.

In a preferred embodiment of the invention, in the chemical compound of the general formula II R13 and R14 and/or R15 and R16 in each case form an unsubstituted or substituted heterocyclic 5-membered ring having at least one heteroatom selected from S, O and N.

In a preferred embodiment of the invention, the chemical compound of the general formula II does not have a ring structure between R13 and R14 and/or between R15 and R16.

In a preferred embodiment of the invention, in the chemical compound of the general formula II R14 and R16 are independently selected from the group consisting of

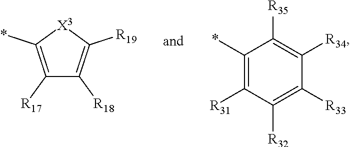

with X₃ O, S, or N—R9 with R9 selected from the group consisting of H, alkyl and aryl;
with R17 to R19 and R31 to R35 independently selected from the group consisting of H, halogen, preferably F and Cl, CN, alkyl, preferably C1-C4-alkyl, O-alkyl, preferably O—C1-C4-alkyl, and S-alkyl, preferably S—C1-C4-alkyl, wherein preferably at least one hydrogen atom is substituted by F.

In a preferred embodiment of the invention, in the chemical compound of the general formula II R17 and/or R18 are H, preferably R17 and R18.

In a preferred embodiment of the invention, in the chemical compound of the general formula II at least R31 and R35 are H.

In a preferred embodiment of the invention, in the chemical compound of the general formula II R31, R32, R34 and R35 are H.

In a further preferred embodiment of the invention, in the chemical compound of the general formula II R31 to R35 are H.

In a further preferred embodiment of the invention, in the chemical compound of the general formula II Z₁ and Z₂ are F, and R1 and R2 are independently selected from the group consisting of H, F, Cl and Br, with the proviso that at least R1 or R2 is Br or Cl.

In a further preferred embodiment of the invention, in the chemical compound of the general formula II Y₁ and Y₃ are CH and Y₂ is CR22, preferably with CR22 selected from the group consisting of F, Br, Cl and CN, or Y₁ is CR21, Y₂ is N and Y₃ is CR23, preferably with CR21 and CR23 H or methyl, or Y₁ is N, Y₂ is CR22 and Y₃ is N, preferably with CR22 H or methyl, wherein R1 and R2 in each case are preferably F or Cl.

In a further preferred embodiment of the invention, the at least one chemical compound is a compound of the general formula III

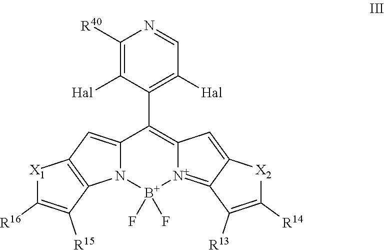

wherein X₁ and X₂ are independently O or S, wherein R⁴⁰ is H, Cl or F, preferably H, and wherein Hal is Br, Cl or F. In a particularly preferred embodiment of the invention, the meso substituent on the BODIPY base skeleton is (4)-3,5-dichloropyridine, i.e. with each Hal=Cl, and R40=H.

In a further preferred embodiment of the invention, the at least one chemical compound is a compound of the general formula IV

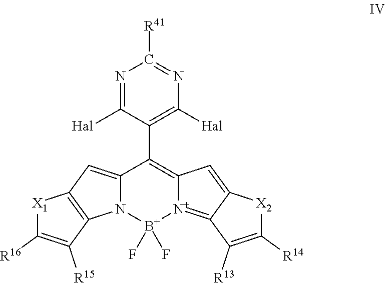

wherein X₁ and X₂ are independently O or S, wherein R⁴¹ is H, Cl or F, preferably H, and wherein Hal is Br, Cl or F.

In a further preferred embodiment of the invention, the at least one chemical compound is a compound of the general formula V

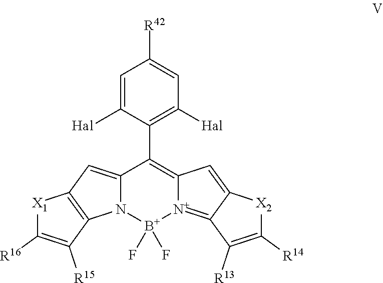

wherein X₁ and X₂ are independently O or S, wherein R⁴² is H, C1-C4-alkyl, Cl or F, and wherein Hal is Br, Cl or F.

In a further preferred embodiment of the invention, in the chemical compound of the general formula II R¹⁴ and R¹⁶ are an unsubstituted or substituted heterocyclic 5-membered ring having at least one heteroatom selected from S, O and N, preferably O and S, wherein preferably R19, R17 and R19, or R18 and R19 are substituted, or an unsubstituted or substituted homocyclic 6-membered ring, wherein preferably R32, R33, or R32 and R34 are substituted, or R31 to R35 are H.

The invention is elucidated in detail hereinafter with reference to the drawings. The figures show:

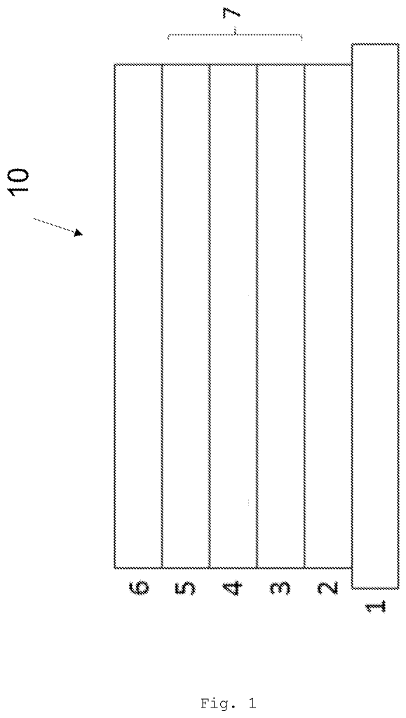

FIG. 1 a schematic representation of a working example of an optoelectronic component in cross section;

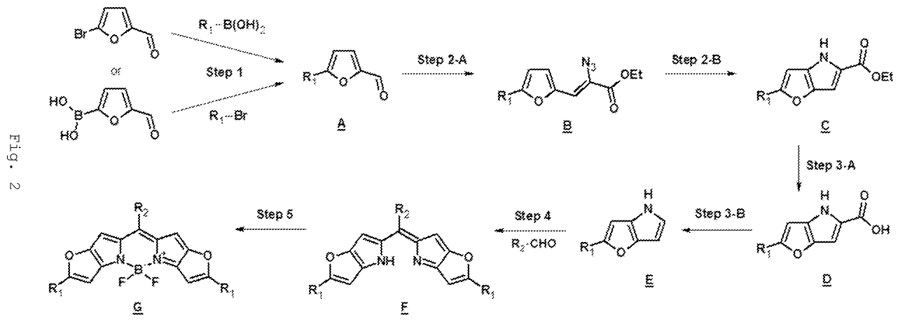

FIG. 2 a schematic representation of a working example of a synthesis scheme for synthesis of compounds of the invention;

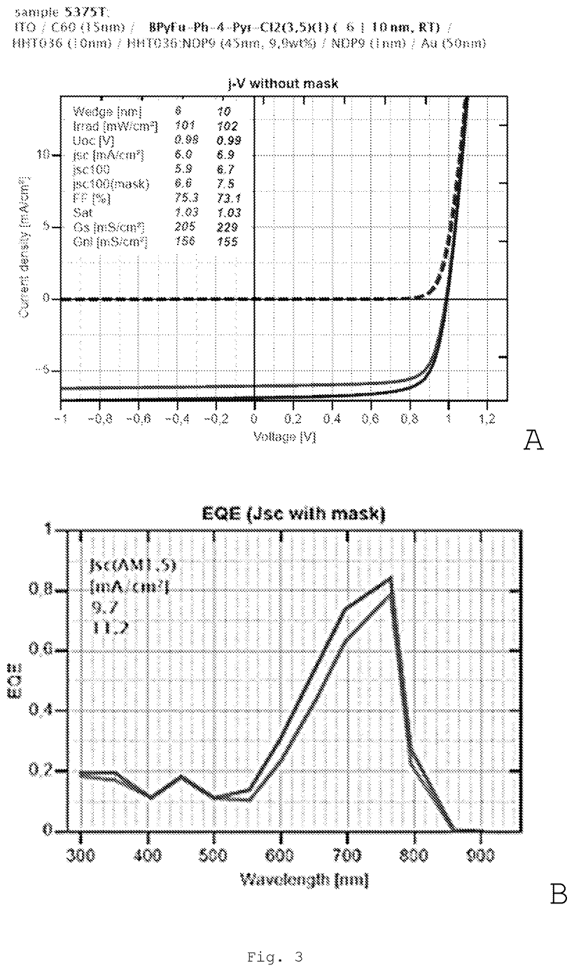

FIG. 3 a graph of the current-voltage curve, the spectral external quantum yield and the fill factor of a PHJ cell comprising compound (40), measured on an organic optoelectronic component;

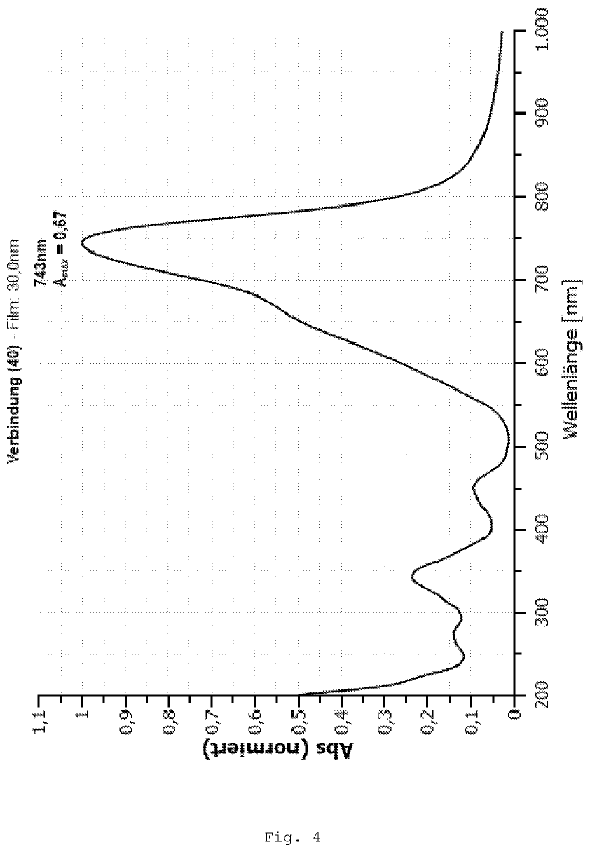

FIG. 4 a graph of the absorption spectrum of compound (40); and

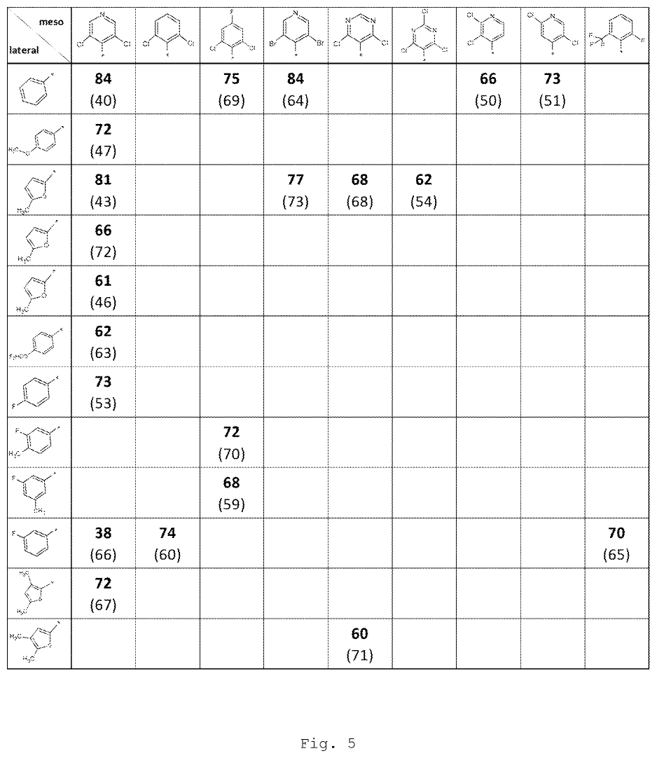

FIG. 5 the maximum external quantum yield (EQEₘₐₓ) of multiple working examples of compounds of the invention in an optoelectronic component.

### WORKING EXAMPLES

FIG. 1 shows a schematic representation of a working example of an optoelectronic component 10 in cross section.

In this working example, the optoelectronic component 10 is an organic photovoltaic element.

The optoelectronic component 10 has a substrate 1. Arranged atop the substrate 1 is a base electrode 2, a top electrode 6, and a layer system 7 comprising at least one photoactive layer 4, wherein the layer system 7 is arranged between the base electrode 2 and the top electrode 6. The at least one photoactive layer 4 is formed as a planar heterojunction (PHJ). The at least one photoactive layer 4 in the form of a planar heterojunction has an acceptor layer and a donor layer. The donor layer of the photoactive layer 4 comprises at least one chemical compound of the general formula I as donor. In this working example, the acceptor layer of the photoactive layer 4 has the fullerene C60 as acceptor; the acceptor may alternatively also be a fullerene derivative or a non-fullerene acceptor (NFA). The chemical compound of the general formula I has the following structure:

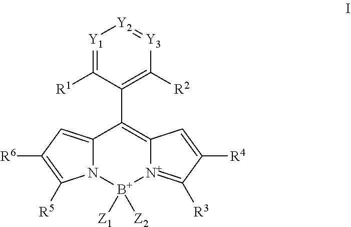

with Y₁ selected from the group consisting of N and CR21, wherein R21 is H, alkyl, O-alkyl, S-alkyl, a halogen, preferably F or Cl, CN, CF₃ or SF₅; with Y₂ selected from the group consisting of N and CR22, wherein R22 is H, alkyl, O-alkyl, S-alkyl, a halogen, preferably F or Cl, CN, CF₃ or SF₅; with Y₃ selected from the group consisting of N and CR23, wherein R23 is H, alkyl, O-alkyl, S-alkyl, a halogen, preferably F or Cl, CN, CF₃ or SF₅;
with Z₁ and Z2 independently selected from the group consisting of F, Cl, CN, CF₃, C₂F₅, OCH₃, and OC₂H₅;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CHF₂, CH₂F or CH₃;
with R3 and R5 independently selected from the group consisting of H, halogen, CN, unsubstituted and aryl- or heteroaryl-substituted alkyl, unsubstituted and aryl- or heteroaryl-substituted alkenyl, O-alkyl, S-alkyl, an unsubstituted and alkyl-substituted heterocyclic 5-membered ring and 6-membered ring, preferably having at least one heteroatom selected from S, O or N, and an unsubstituted and alkyl-substituted homocyclic 6-membered ring, wherein the unsubstituted or substituted heterocyclic 5-membered ring or 6-membered ring, or the unsubstituted or substituted homocyclic 6-membered ring may be fused to a further unsubstituted or substituted heterocyclic 5-membered ring or 6-membered ring; with R4 and R6 independently selected from the group consisting of H, halogen, CN, alkyl, alkenyl, O-alkyl, S-alkyl, an unsubstituted and halogen-, alkyl- and/or O-alkyl-substituted heterocyclic 5-membered ring and 6-membered ring, preferably having at least one heteroatom selected from S, O and N, and an unsubstituted and halogen-, alkyl- and/or O-alkyl-substituted homocyclic 6-membered ring;
wherein R3 and R4 and/or R5 and R6 may in each case together form an unsubstituted or halogen-, alkyl-, O-alkyl-, aryl- and/or -substituted heterocyclic 5-membered ring or 6-membered ring, preferably having at least one heteroatom selected from S, O and N, or an unsubstituted or halogen-, alkyl-, O-alkyl-, aryl- and/or heteroaryl-substituted homocyclic 6-membered ring.

The general preparation of the compounds of the invention is known to those skilled in the art from the prior art. Reference in this context is made in particular to international applications WO2007126052A1 and EP3617214A1.

In one configuration of the invention, the optoelectronic component 10 has a layer system 7 having at least one light-absorbing photoactive layer 4, wherein the at least one light-absorbing photoactive layer 4 comprises the at least one compound of the general formula I.

In a further configuration of the invention, the layer system 7 has at least two photoactive layers 4, preferably at least three photoactive layers 4, or preferably at least four photoactive layers 4. In a further configuration of the invention, the optoelectronic component 10 is formed as a tandem cell, triple cell or multiple cell.

In one working example, the organic photovoltaic element has a substrate 1 made of glass, but the substrate 1 may also be formed from a film, for example of PET. Atop the substrate 1 is a base electrode 2, for example made of ITO. Disposed thereon is the layer system 7 having an electron-transporting layer 3 (ETL) and a photoactive layer 4 in the form of a planar heterojunction, having at least one compound of the invention as donor material, and an acceptor material, e.g. fullerene C60. Disposed above the latter is a p-doped hole-transport layer 5 (HTL), and a top electrode 6 made of gold or aluminum.

In one configuration of the invention, the optoelectronic component 10 comprising a compound of the general formula I in a photoactive layer 4 in the form of a planar heterojunction is an organic optoelectronic component, preferably an organic photovoltaic element, an OFET, an OLED or an organic photodetector.

The organic materials are printed, glued, coated, vapor-deposited or otherwise applied to the foils in the form of thin films or small volumes. Useful methods for the production of the thin layers are likewise those that are also used for electronics on glass, ceramic or semiconductive carriers. Vacuum evaporation was used for production of the layer system in the present working examples.

FIG. 2 shows a schematic representation of a working example of a synthesis scheme for synthesis of compounds of the invention.

The experimental procedure for the synthesis of compounds of the general formula I is shown in FIG. 2.

### General Procedure for Step 2-A:

Aldehyde A (1.00 eq.) was dissolved/suspended in 9 vol of anhydrous ethanol. Ethyl trifluoroacetate (1.50 eq.) was added, and the resultant mixture was cooled down to 0° C. Subsequently, sodium ethoxide solution (21 wt %, 1.50 eq.) was added and, after 5 min, ethyl 2-azidoacetate (1.50 eq.) was added gradually at a temperature below 5° C. within 10 min. The mixture was then stirred at 0° C. for 30 min and warmed gradually to room temperature, with continuation of the stirring for 4 hours. The reaction mixture was dissolved in 21 vol of ethanol, and the precipitate was filtered off and washed with cooled anhydrous ethanol, giving intermediate B.

### General Procedure for Step 2-B:

Intermediate B was dissolved in toluene, and the resultant solution was dried over anhydrous sodium sulfate and filtered. A flask was charged with 43 vol of anhydrous toluene under argon and heated under reflux. The solution of intermediate B was introduced into a dropping funnel and added gradually to the toluene heated under reflux within 15 min. The resultant solution was heated for a further 15 min. The solvent was removed under reduced pressure, giving a brown solid as crude product. The crude product was suspended in 8 vol of petroleum ether and treated with ultrasound. The resultant precipitate was filtered off, washed with petroleum ether and dried under reduced pressure, giving pyrrole ester C.

### General Procedure for Step 3-A:

Pyrrole ester C (1.00 eq.) was suspended in 19 vol of ethanol, and a solution of 5.0 eq. of NaOH in 4 vol of water was added. The mixture was stirred at 75° C. over the course of 1 hour and then 7.0 eq of AcOH in 11 vol of water was added, in order to obtain a pH of ˜4. The product was filtered off and washed with water and then toluene, giving pyrrole acid D.

### General Procedure for Step 3-B:

Pyrrole acid D (1.00 eq.) was dissolved in 21 vol of ethanolamine. The mixture was heated to 150° C. and stirred for 4 hours. After cooling to 50° C., 32 vol of heptane was added. The mixture was cooled further to 10° C., and the product was filtered off, washed with water and heptane and dried under reduced pressure, giving pyrrole E.

### General Procedure for Step 4:

Pyrrole E (2.00 eq.) and aldehyde (1.00 eq.) were dissolved/suspended in 30 vol of dichloromethane. Trifluoroacetic acid (0.10 eq.) was added dropwise at room temperature, and the mixture was stirred over the course of 3 hours. p-Chloranil (1.05 eq.) was added dropwise over the course of 5 min, and the mixture was mixed at room temperature for 30 min. The mixture was diluted with 25 vol of methanol and then concentrated under reduced pressure (40° C. in a water bath) in order to largely remove dichloromethane. Subsequently, the resultant suspension was stirred at 0° C. for 90 min and then filtered. The isolated solids were washed with cold methanol and dried under reduced pressure, giving dipyrrin F.

### General Procedure (Synthesis) for Step 5:

Dipyrrin F (1.00 eq.) was suspended in 42 vol of anhydrous toluene. The mixture was stirred at 55° C., and N,N-diisopropylethylamine (1.50 eq.) was added. A solution of boron trifluoride diethyletherate (4.00 eq.) in 10 vol of anhydrous toluene was added gradually. The mixture was stirred at 55° C. until dissolution was complete. The reaction mixture was cooled to 0° C. and stirred at that temperature for one hour. The precipitate was filtered, washed with toluene and methanol, and then dried under reduced pressure, giving crude BODIPY G. The crude BODIPY G was purified by recrystallization, and purified BODIPY G was obtained.

### Synthesis of the Compounds

### Synthesis of 5-phenylfuran-2-carbaldehyde A-1

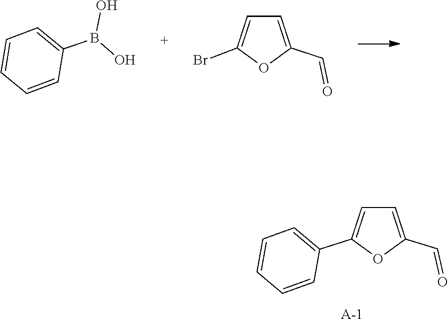

The synthesis of 5-phenylfuran-2-carbaldehyde A-1 can be conducted in accordance with Li et al. (J. Am. Chem. Soc. 2017, 139 (39), 13636-13639).

### Synthesis of Pyrrole Ester C-1

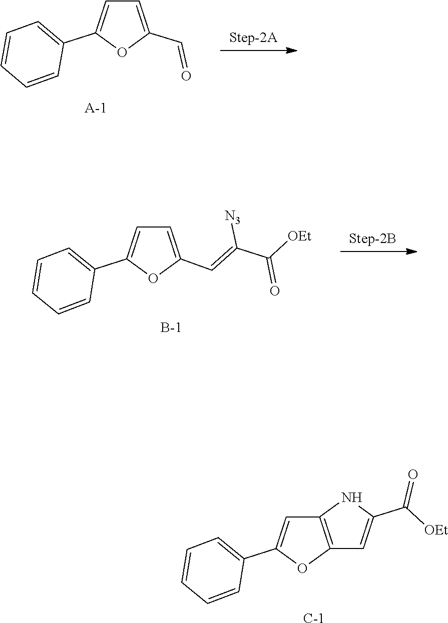

Using the compound 5-phenylfuran-2-carbaldehyde A-1 (8.61 g, 50.0 mmol) according to step 2-A and step 2-B, compound C-1 was isolated as a white to brownish solid (8.33 g, 65% yield). 1H NMR (400 MHz, acetone-d6) δ 10.70 (m, 1H), 7.82 (m, 2H), 7.44 (m, 2H), 7.32 (m, 1H), 7.03 (m, 1H), 6.78 (m, 1H), 4.30 (q, J=8.0 Hz, 2H), 1.33 (t, J=8.0 Hz, 3H).

### Synthesis of Pyrrole Acid D-1

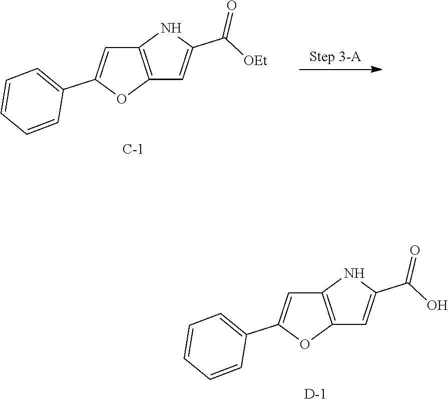

According to the general process for step 3-A using pyrrole ester C-1 (58.0 g, 0.227 mol), compound D-1 was isolated as a beige solid (50.3 g, 97% yield).

### Synthesis of Pyrrole E-1

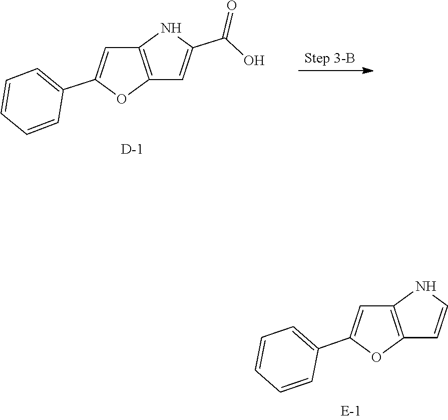

According to the general process for step 3-B using pyrrole acid D-1 (50.0 g, 0.220 mol), compound E-1 was isolated as a brownish solid (36.6 g, 91% yield). 1H NMR (400 MHz, acetone-d6) δ 9.86 (m, 1H), 7.73 (m, 2H), 7.37 (m, 2H), 7.21 (m, 1H), 6.96 (m, 1H), 6.88 (m, 1H), 6.11 (m, 1H).

### Synthesis of Dipyrrin F-1

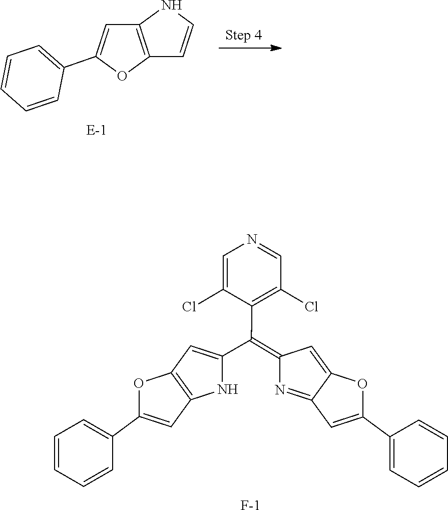

According to the general process for step 4 using pyrrole E-1 (5.13 g, 28.0 mmol) and 3,5-dichloro-4-pyridinecarboxaldehyde (2.54 g, 14.0 mmol), compound F-1 was isolated as a green crystalline solid (6.30 g, 86% yield).

### Synthesis of BODIPY G-1

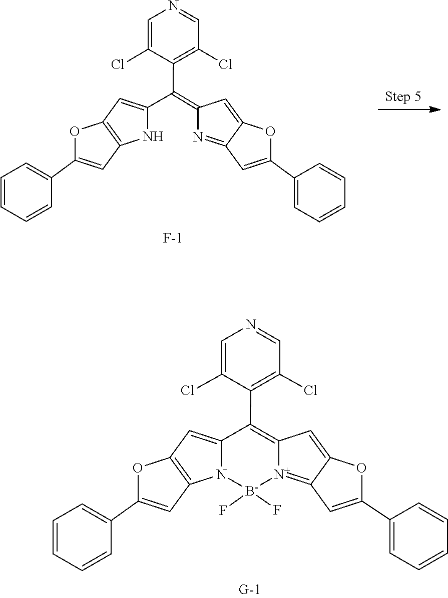

According to the general process for step 5 using dipyrrin F-1 (6.30 g, 12.1 mmol), compound G-1 was isolated, and was purified by recrystallization in toluene (800 ml). A green crystalline solid was obtained (4.10 g, 60% yield).

FIG. 3 shows a graph of the current-voltage curve, the spectral external quantum yield and the fill factor of a PHJ cell comprising compound (40), measured on an organic optoelectronic component 10. Identical and functionally identical elements have been given the same reference numerals, and so reference is made to the description above in this respect. In this working example, the optoelectronic component 10 is an organic photovoltaic element.

In order to examine the compounds, i.e. the use thereof as absorber materials in organic optoelectronic components 10, the current-voltage curve of a PHJ cell was measured (FIG. 3A), and the external quantum yield as a function of wavelength was plotted (FIG. 3B). The current-voltage curve contains indices that characterize the organic photovoltaic element. The most important indices here are the fill factor FF, the open-circuit voltage U_{oc}, and the short-circuit current Jsc.

The current-voltage curve of a PHJ cell with the construction: glass with ITO/C60 (15 nm)/compound (40) (10 nm, RT)/NHT169 (10 nm)/NHT169:NDP9 (45 nm, 9.9 wt %)/NDP9 (1 nm)/Au (50 nm) was determined. The parameters of the cell were measured under AM1.5 illumination (AM=Air Mass; AM=1.5; in this spectrum, the global radiation power is 1000 W/m²; AM=1.5 as standard value for the analysis of solar modules), where the photoactive layer comprises a planar heterojunction (PHJ). In the photoactive layer 4, the donor layer of compound (40) was applied separately from the acceptor layer of C60, in the form of a planar heterojunction. ITO serves here as base electrode 2, and the adjacent fullerene C60 as electron transport layer (ETL) 3, adjoined by the photoactive layer 4 having an acceptor layer disposed on the electron transport layer 3 and a donor layer, followed by NHT169 as hole transport layer (HTL) 5 and NDP9-doped NHT169. The top electrode is formed from gold. NDP9 is a commercial p-dopant from Novaled GmbH. NHT169 is an HTL matrix material from Novaled GmbH.

The individual layers of the optoelectronic component 10, especially the photoactive layer 4, can be applied under reduced pressure by evaporating the corresponding material. Compound (40) shows good evaporability under reduced pressure.

In the optoelectronic component comprising compound (40) in a planar heterojunction, the fill factor FF is 73.1%, the open-circuit voltage U_{oc} is 0.99 V, and the short-circuit current Jsc is 11.2 mA/cm2. The EQEₘₐₓ of such an organic photovoltaic element is 84%.

FIG. 4 shows a graph of an absorption spectrum of compound (40). Identical and functionally identical elements have been given the same reference numerals, and so reference is made to the description above in this respect.

The construction of the optoelectronic component 10 corresponds to that of FIG. 2; the donor in the photoactive layer 4 which is in the form of a planar heterojunction is likewise compound (40).

The absorption maximum Amax of compound (40) is 743 nm.

FIG. 5 shows the maximum external quantum yield (EQEmax) of multiple working examples of compounds of the invention in an optoelectronic component 10. Identical and functionally identical elements have been given the same reference numerals, and so reference is made to the description above in this respect. In this working example, the optoelectronic component 10 is an organic photovoltaic element.

The construction of the optoelectronic component 10 corresponds to that of FIG. 2, where the donor in each case in the photoactive layer 4 in the form of a planar heterojunction is different.

The following donors from the inventive compounds of the general formula I were used:

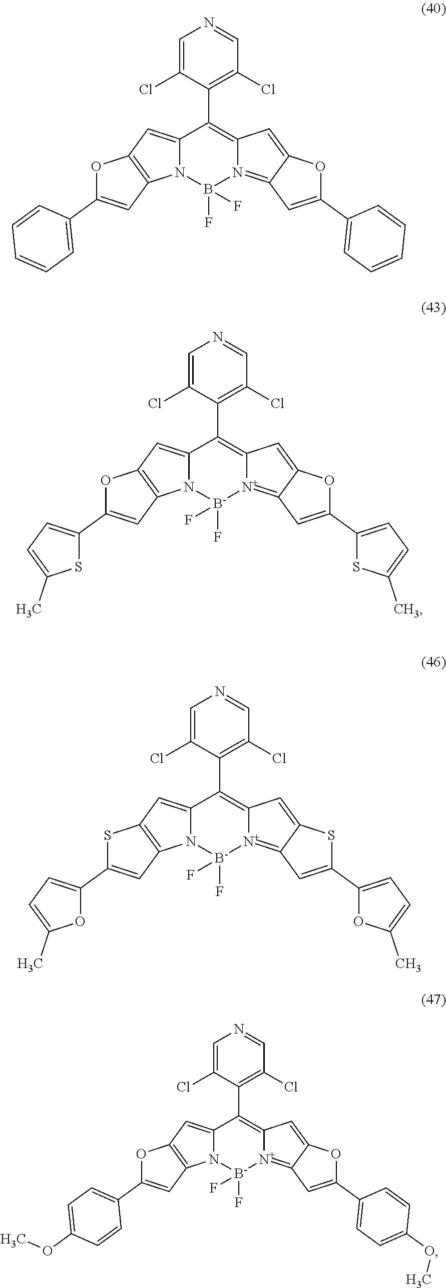

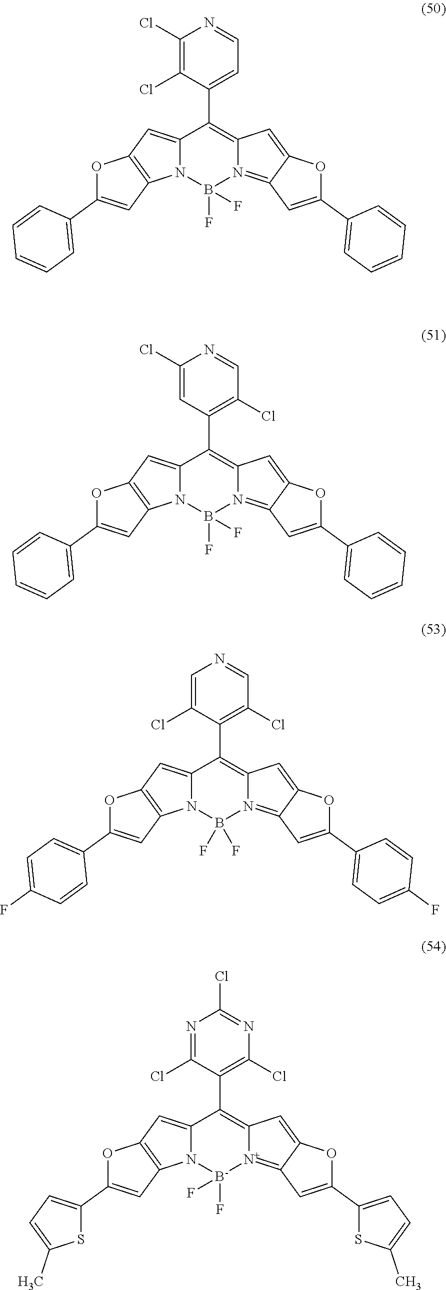

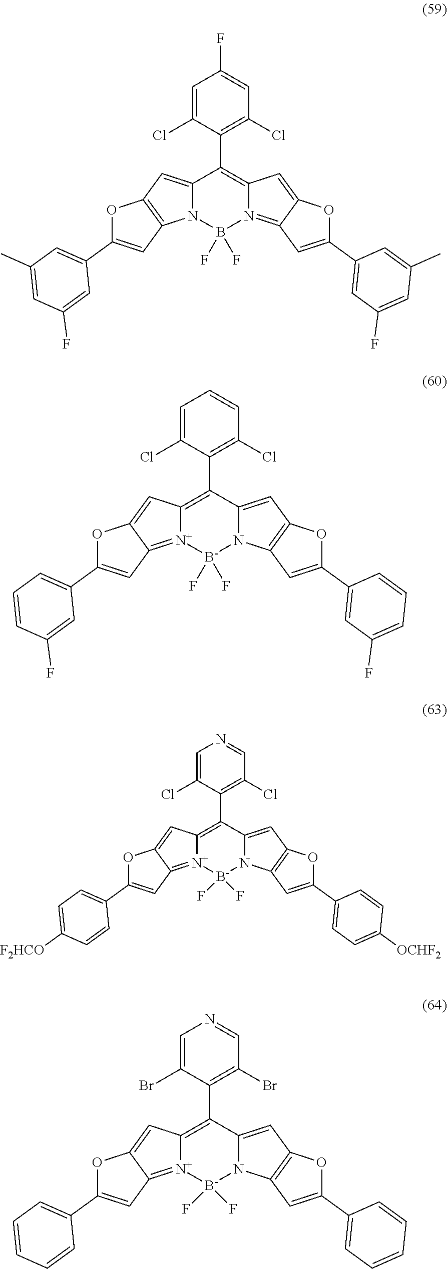

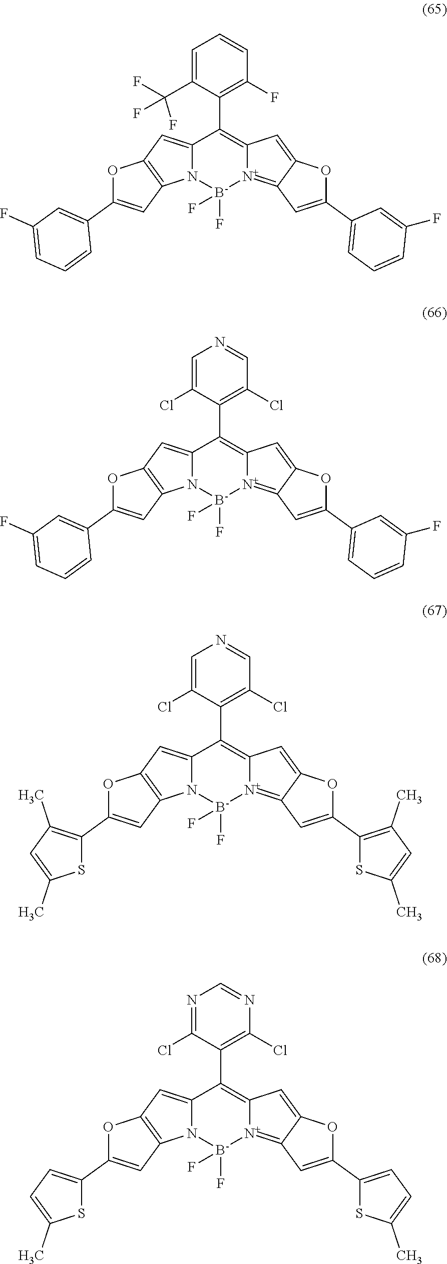

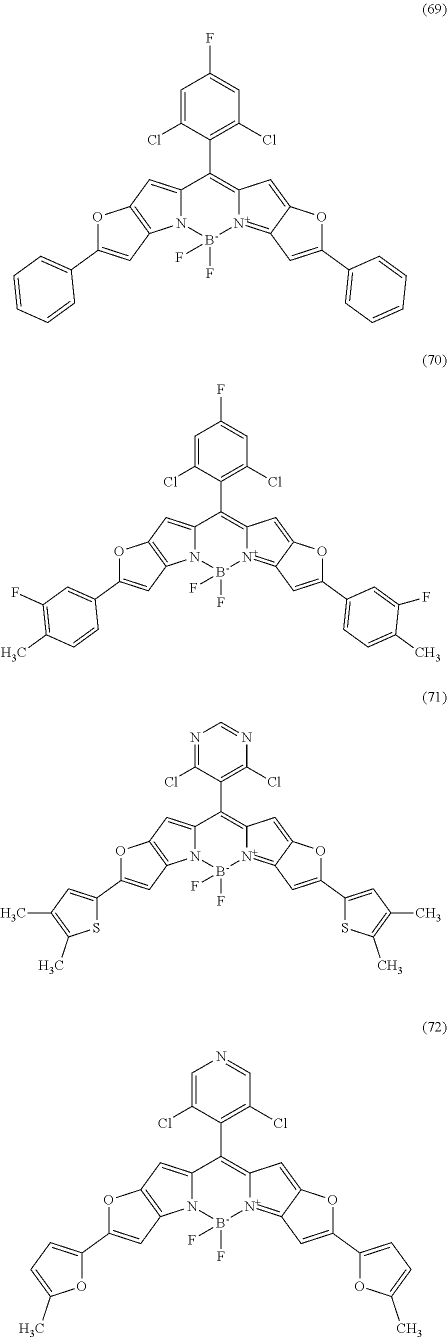

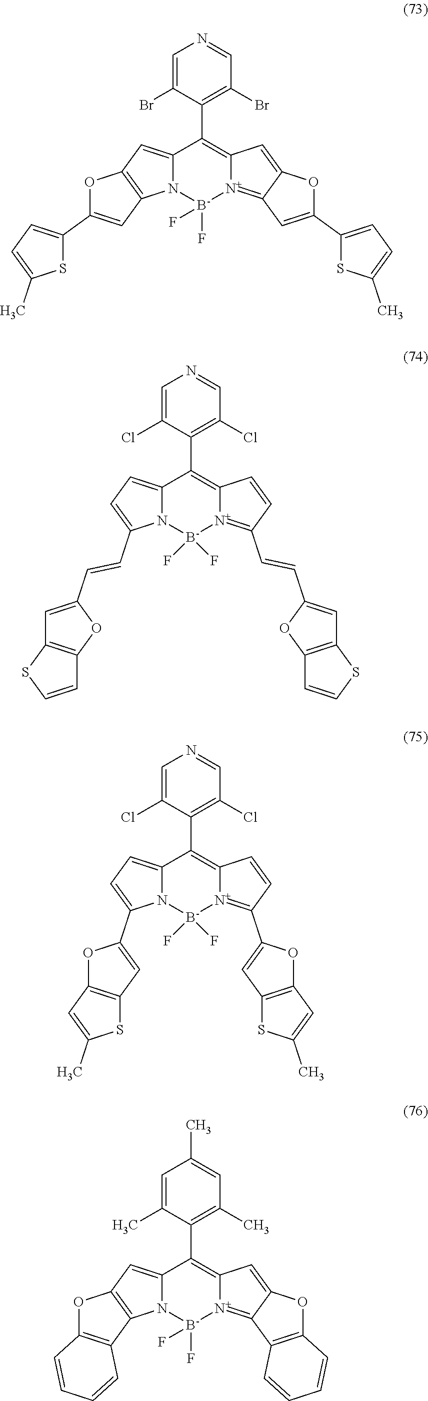

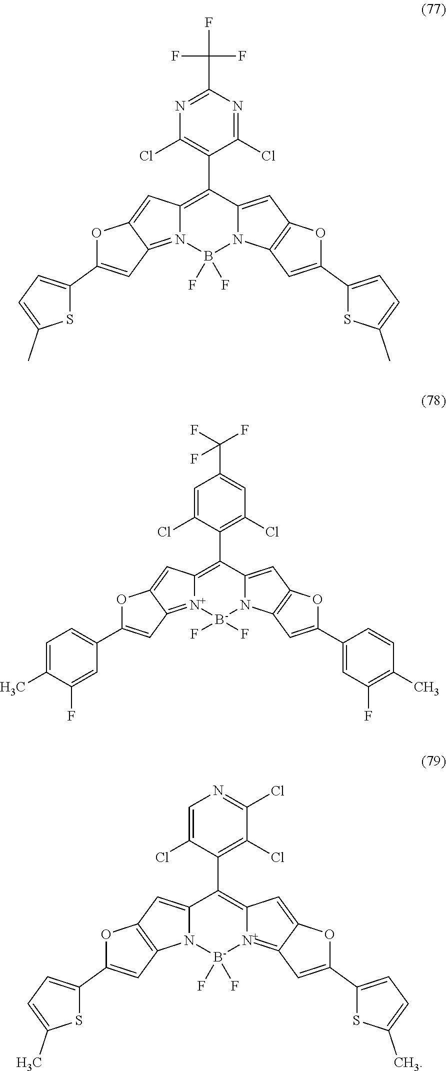

Table 1 shows the absorption maxima λmax of multiple compounds of the invention in the film. The optical properties were determined experimentally. The absorption maxima λmax were determined from 30 nm-thick vacuum vapor deposition layers on quartz glass by means of a photometer. Table 1 shows the photovoltaic parameters Uoc, Jsc and FF of multiple compounds of the invention with the respective EQEₘₐₓ. The maximum EQE is referred to as EQEₘₐₓ, and is an essential parameter for description of the efficiency of photovoltaic elements. The efficiency of a photovoltaic element increases with higher EQEₘₐₓ for the corresponding spectral region. The EQEₘₐₓ of the compounds of the invention is in a range from 60% to 84%.

TABLE 1

| | U_{oc} | FF | I_{sc} (EQE) | EQEₘₐₓ | Absorption max |
|---|---|---|---|---|---|
| Compound | [V] | [%] | [mA] | [%] | (film) [nm] |
| (40) | 0.99 | 73.1 | 11.2 | 84 | 743 |
| (43) | 0.71 | 70.8 | 11.3 | 81 | 815 |
| (47) | 0.79 | 72.5 | 10.4 | 72 | 776 |
| (50) | 1.02 | 50.3 | 9.5 | 66 | 729 |
| (51) | 1.02 | 69 | 10.2 | 73 | 731 |
| (53) | 1.06 | 52.8 | 9.5 | 73 | 742 |
| (54) | 0.81 | 65.4 | 9.2 | 62 | 821 |
| (59) | 1.06 | 66.9 | 9.5 | 68 | 738 |
| (60) | 1.03 | 72.4 | 10 | 74 | 728 |
| (63) | 1.07 | 53.6 | 7.8 | 62 | 744 |
| (64) | 0.98 | 73.7 | 10.3 | 84 | 746 |
| (65) | 1.09 | 58.6 | 9.4 | 70 | 696 |
| (67) | 0.68 | 52.0 | 10.8 | 72 | 830 |
| (68) | 0.78 | 53.1 | 10.1 | 68 | 819 |
| (69) | 0.94 | 73.6 | 10.2 | 75 | 735 |
| (70) | 1.01 | 76.6 | 9.2 | 72 | 739 |
| (71) | 0.71 | 52.3 | 9.6 | 64 | 836 |
| (72) | 0.71 | 60.3 | 9.7 | 66 | 813 |
| (73) | 0.73 | 64.7 | 10.5 | 77 | 816 |
| (75) | 0.73 | 55.0 | 6.9 | 52 | 821 |
| (77) | 0.82 | 54.9 | 10.0 | 69 | |

An overview of the EQEₘₐₓ for the specific working examples of the inventive chemical compound of the general formula I in PHJ cells of the organic photovoltaic element is shown in the overview in FIG. 5 depending on the meso group on the BODIPY base skeleton and the lateral groups (corresponding to R14/R16 of the compound having the general formula III). The corresponding number of the compound is given in brackets in each case. PHJ cells comprising compounds of the invention show a particularly high EQEₘₐₓ, in particular by comparison with noninventive compounds, in particular noninventive BODIPY compounds that do not have structural features of the invention in the meso position.

The experimental data of the compounds of the invention in photoactive layers 4 in the form of a planar heterojunction in organic photovoltaic elements demonstrate that the compounds of the invention are of very good suitability as absorber material in planar heterojunctions, and lead to improved efficiency of photovoltaic elements having such photoactive layers 4.

1. An optoelectronic component, preferably a photovoltaic element, having a base electrode, a top electrode and a layer system having at least one photoactive layer, wherein the layer system is disposed between the base electrode and the top electrode, wherein at least one photoactive layer takes the form of a planar heterojunction (PHJ), and wherein the at least one photoactive layer is formed as a planar heterojunction comprises at least one chemical compound of the general formula I 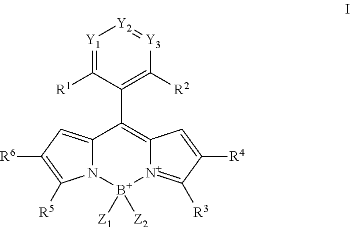
with Y₁ selected from the group consisting of N and CR21, wherein R21 is H, alkyl, O-alkyl, S-alkyl, a halogen, preferably F or Cl, CN, CF₃ or SF₅;
with Y₂ selected from the group consisting of N and CR22, wherein R22 is H, alkyl, O-alkyl, S-alkyl, a halogen, preferably F or Cl, CN, CF₃ or SF₅;
with Y₃ selected from the group consisting of N and CR23, wherein R23 is H, alkyl, O-alkyl, S-alkyl, a halogen, preferably F or Cl, CN, CF₃ or SF₅;
with Z₁ and Z₂ independently selected from the group consisting of F, Cl, CN, CF₃, C₂F₅, OCH₃, and OC₂H₅;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CHF₂, CH₂F or CH₃;
with R3 and R5 independently selected from the group consisting of H, halogen, CN, unsubstituted and aryl- or heteroaryl-substituted alkyl, unsubstituted and aryl- or heteroaryl-substituted alkenyl, O-alkyl, S-alkyl, an unsubstituted and alkyl-substituted heterocyclic 5-membered ring and 6-membered ring, preferably having at least one heteroatom selected from S, O or N, and an unsubstituted and alkyl-substituted homocyclic 6-membered ring, wherein the unsubstituted or substituted heterocyclic 5-membered ring or 6-membered ring, or the unsubstituted or substituted homocyclic 6-membered ring may be fused to a further unsubstituted or substituted heterocyclic 5-membered ring or 6-membered ring;
with R4 and R6 independently selected from the group consisting of H, halogen, CN, alkyl, alkenyl, O-alkyl, S-alkyl, an unsubstituted and halogen-, alkyl- and/or O-alkyl-substituted heterocyclic 5-membered ring and 6-membered ring, preferably having at least one heteroatom selected from S, O and N, and an unsubstituted and halogen-, alkyl- and/or O-alkyl-substituted homocyclic 6-membered ring;
or wherein R3 and R4 and/or R5 and R6 in each case together form an unsubstituted or halogen-, alkyl-, O-alkyl-, aryl- and/or heteroaryl-substituted heterocyclic 5-membered ring or 6-membered ring, preferably having at least one heteroatom selected from S, O and N, or an unsubstituted or halogen-, alkyl-, O-alkyl-, aryl- and/or heteroaryl-substituted homocyclic 6-membered ring.

2. The optoelectronic component as claimed in claim 1, wherein Z₁ and Z₂ are F; and/or
where R1 and R2 are independently selected from the group consisting of H, F, Cl, Br, CN, CF₃, Me, Et, OMe, SMe, OEt, SEt, Pr, and iPr, with the proviso that at least R1 or R2 is Br or Cl, wherein preferably R1 and R2 are not H; or
wherein R1 and R2 are independently selected from the group consisting of Cl, Br, CF₃, CN, Me, Et, OMe, SMe, OEt, and SEt, with the proviso that at least R1 or R2 is Cl, Br, CF₃ or Me; or
wherein R1 and R2 are selected from the group consisting of Br, Cl, CF₃, CHF₂, and CH₂F.

3. The optoelectronic component as claimed in claim 1 or 2, wherein Y₁ is selected from the group consisting of N and CR21, wherein R21 is H or Cl, and/or
wherein Y₂ is selected from the group consisting of N and CR22, wherein R22 is H, CH₃, O—CH₃, S—CH₃, F, Cl, CF₃ or SF₅, preferably N or CH, and/or
wherein Y₃ is selected from the group consisting of N and CR23, wherein R23 is H or Cl;
wherein preferably one Y₁, Y₂, Y₃ is an N, or two Y₁, Y₂, Y₃ are an N.

4. The optoelectronic component as claimed in any of the preceding claims, wherein R3 and R4 and/or R5 and R6 form an unsubstituted or substituted heterocyclic 5-membered ring or 6-membered ring having at least one heteroatom selected from O, S and N, preferably from O and S, or an unsubstituted or substituted homocyclic 6-membered ring, or wherein R3 and R4 and/or R5 and R6 form an unsubstituted or substituted heterocyclic 5-membered ring, preferably a substituted heterocyclic 5-membered ring, having at least one heteroatom selected from O, S and N, preferably O and S, or an unsubstituted or substituted homocyclic 6-membered ring, preferably an unsubstituted homocyclic 6-membered ring.

5. The optoelectronic component as claimed in any of the preceding claims, wherein the at least one chemical compound is a compound of the general formula II 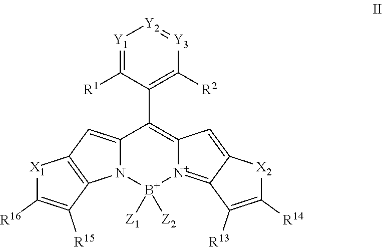
with Y₁ selected from the group consisting of N and CR21, wherein R21 is H, alkyl, O-alkyl, S-alkyl, a halogen, preferably F or Cl, CN or CF₃;
with Y₂ selected from the group consisting of N and CR22, wherein R22 is H, alkyl, O-alkyl, S-alkyl, a halogen, preferably F or Cl, CN or CF₃;
with Y₃ selected from the group consisting of N and CR23, wherein R23 is H, alkyl, O-alkyl, S-alkyl, a halogen, preferably F or Cl, CN or CF₃;
with Z₁ and Z₂ F or CF₃;
with X₁ and X₂ independently O, S or N—R8 with R8 selected from the group consisting of H, alkyl and aryl, wherein preferably X₁ and X₂ are S or X₁ and X₂ are O;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CH₂F, CHF₂ or CH₃;
wherein R13 and R15 are independently selected from the group consisting of H, halogen, CN, alkyl, O-alkyl and S-alkyl, preferably H or Cl-C4-alkyl;
wherein R14 and R16 are independently selected from the group consisting of an unsubstituted and halogen-, alkyl-, fluorinated alkyl-, O-alkyl- and/or fluorinated O-alkyl-substituted heterocyclic 5-membered ring or 6-membered ring, preferably having a heteroatom independently selected from S, O and N, and an unsubstituted and halogen-, alkyl-, fluorinated alkyl-, O-alkyl- and/or fluorinated O-alkyl-substituted homocyclic 6-membered ring, preferably from an unsubstituted and substituted heterocyclic 5-membered ring, and an unsubstituted and substituted homocyclic 6-membered ring.

6. The optoelectronic component as claimed in claim 5, wherein R14 and R16 are independently selected from the group consisting of 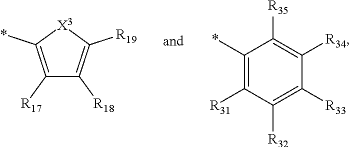
with X₃ O, S, or N—R9 with R9 selected from the group consisting of H, alkyl and aryl;
with R17 to R19 and R31 to R35 independently selected from the group consisting of H, halogen, preferably F and Cl, CN, alkyl, preferably C1-C4-alkyl, O-alkyl, preferably O—C1-C4-alkyl, and S-alkyl, preferably S—C1-C4-alkyl, wherein preferably at least one hydrogen atom is substituted by F.

7. The optoelectronic component as claimed in claim 5 or 6, wherein Z₁ and Z₂ are F, and with R1 and R2 independently selected from the group consisting of H, F, Cl, Br, CH₃, CH₂F, CHF₂ and CF₃, with the proviso that at least R1 or R2 is Br, Cl or CF₃.

8. The optoelectronic component as claimed in any of the preceding claims, wherein Y₁ and Y₃ are CH and Y₂ is CR22, preferably with CR22 selected from F, Br, Cl, and CN, or Y₁ is CR21, Y₂ is N and Y₃ is CR23, preferably with CR21 and CR23 H or methyl, or Y₁ is N, Y₂ is CR22 and Y₃ is N, preferably with CR22 H or methyl.

9. The optoelectronic component as claimed in any of the preceding claims, wherein the at least one chemical compound is a compound of the general formula III 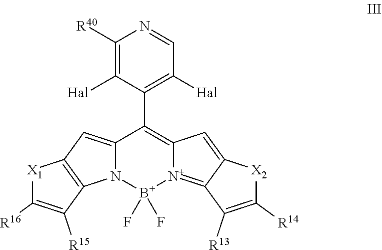
wherein X₁ and X₂ are independently O or S, wherein R⁴⁰ is H, Cl or F, preferably H, and wherein Hal is Br, Cl or F.

10. The optoelectronic component as claimed in any of the preceding claims, wherein the at least one chemical compound is a compound of the general formula IV 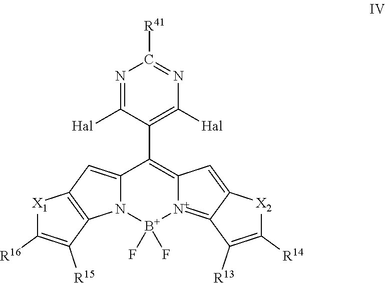
wherein X₁ and X₂ are independently O or S, wherein R⁴¹ is H, F, Cl, Br, CF₃ or C1-C4-alkyl, preferably H or Cl, and wherein Hal is Br, Cl or F.

11. The optoelectronic component as claimed in any of the preceding claims, wherein the at least one chemical compound is a compound of the general formula V 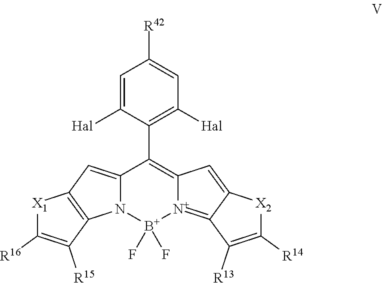
wherein X₁ and X₂ are independently O or S, wherein R⁴² is H, F, Cl, CF₃ or C1-C4-alkyl, and wherein Hal is Br, Cl or F.

12. The optoelectronic component as claimed in any of the preceding claims, wherein R¹⁴ and R¹⁶ are independently an unsubstituted or halogen-, alkyl- and/or O-alkyl-substituted heterocyclic 5-membered ring having at least one heteroatom selected from S, O and N, preferably O and S, wherein preferably R19, or R17 and R19, or R18 and R19 are substituted, or an unsubstituted or a halogen-, alkyl-, fluorinated alkyl-, O-alkyl- and/or fluorinated O-alkyl-substituted homocyclic 6-membered ring, wherein preferably R32, R33, or R32 and R34, are substituted, or, preferably, R31 to R35 are H.

13. The optoelectronic component as claimed in any of the preceding claims, wherein the compound is selected from the group consisting of:

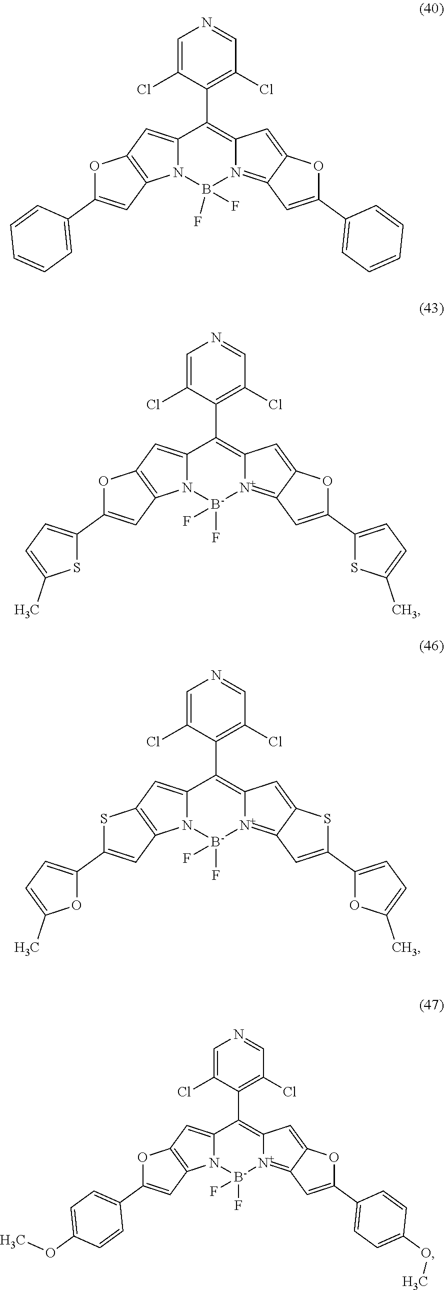

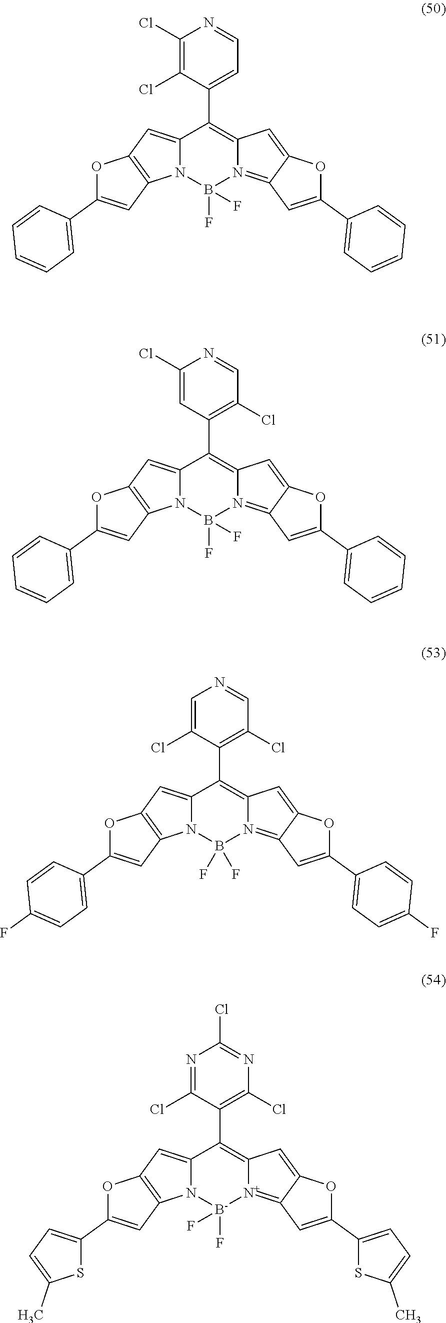

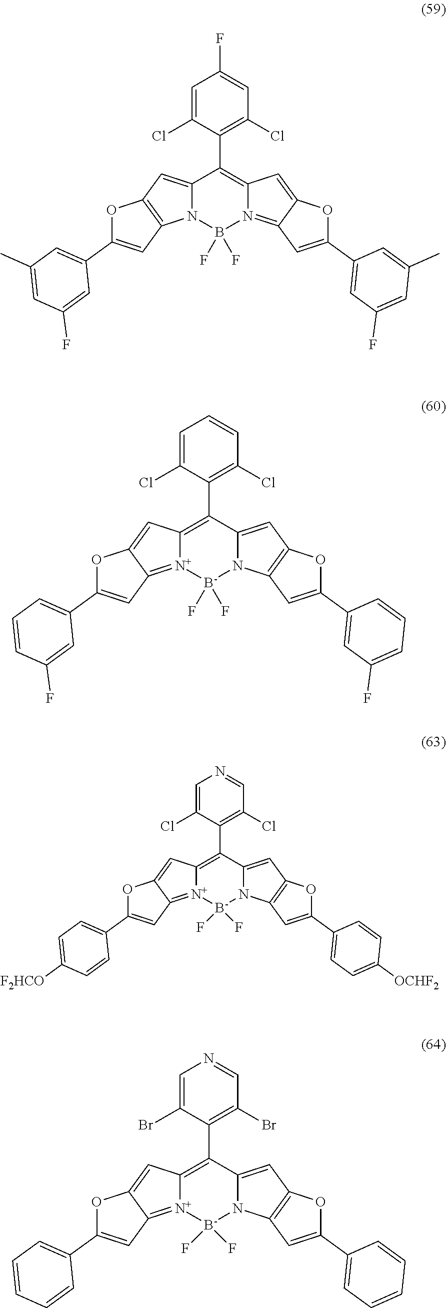

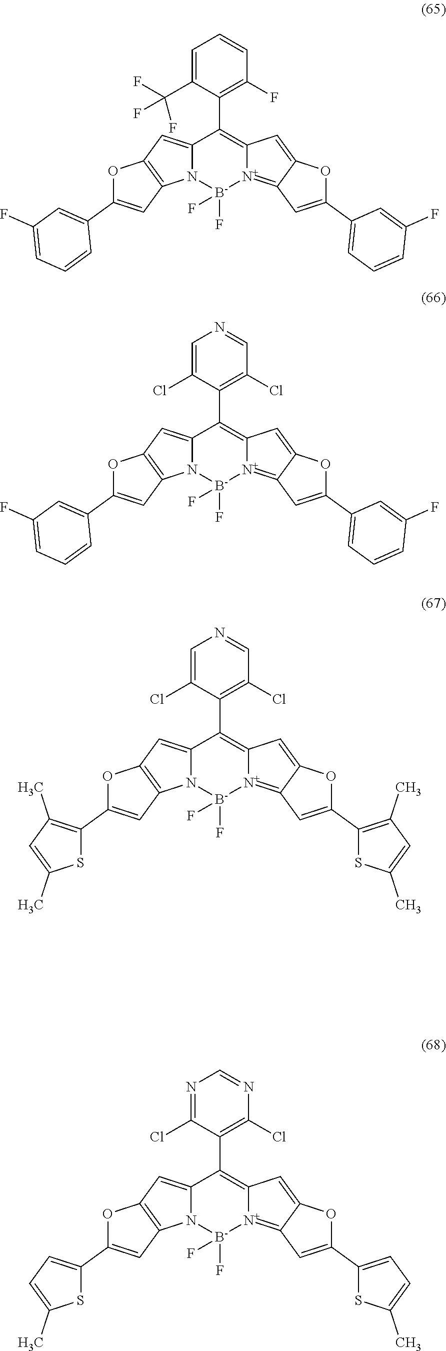 [SMILES: Fc1cccc(-c2cc3c(o2)=CC2=C(c4c(F)cccc4C(F)(F)F)c4cc5oc(-c6cccc(F)c6)cc5n4[B-](F)(F)[N+]=32)c1 ; Fc1cccc(-c2cc3c(o2)=CC2=C(c4c(Cl)cncc4Cl)c4cc5oc(-c6cccc(F)c6)cc5n4[B-](F)(F)[N+]=32)c1 ; Cc1cc(C)c(-c2cc3c(o2)=CC2=C(c4c(Cl)cncc4Cl)c4cc5oc(-c6sc(C)cc6C)cc5n4[B-](F)(F)[N+]=32)s1 ; Cc1ccc(-c2cc3c(o2)=CC2=C(c4c(Cl)ncnc4Cl)c4cc5oc(-c6ccc(C)s6)cc5n4[B-](F)(F)[N+]=32)s1]

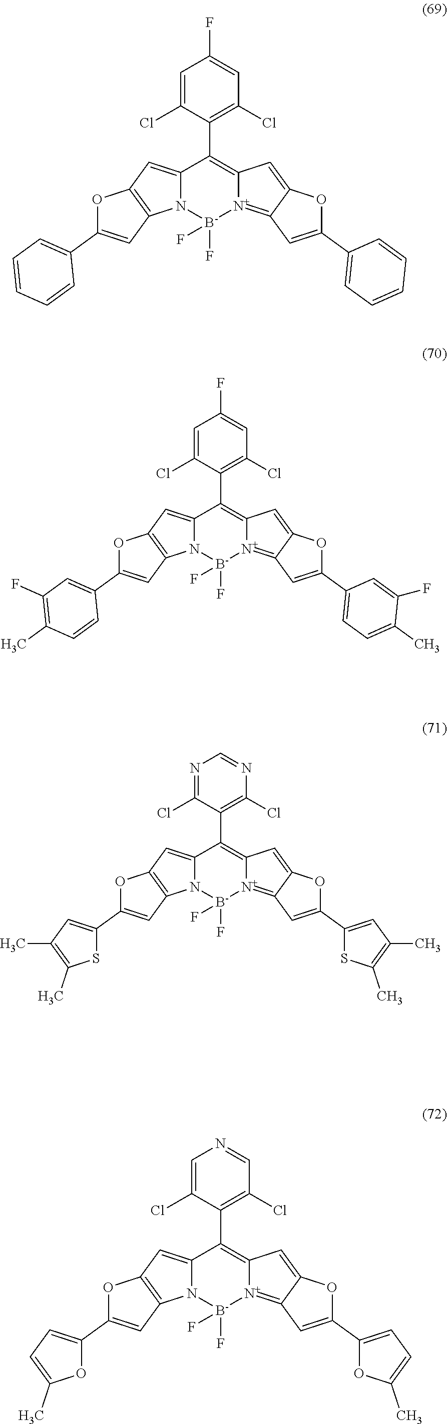

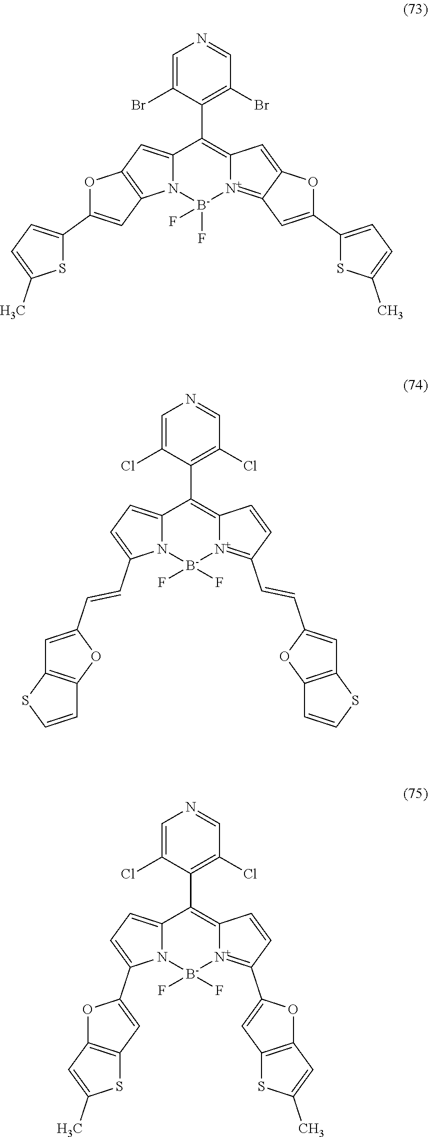 [SMILES: Cc1ccc(-c2cc3c(o2)=CC2=C(c4c(Br)cncc4Br)c4cc5oc(-c6ccc(C)s6)cc5n4[B-](F)(F)[N+]=32)s1 ; F[B-]1(F)n2c(/C=C/c3cc4sccc4o3)ccc2C(c2c(Cl)cncc2Cl)=C2C=CC(/C=C/c3cc4sccc4o3)=[N+]21 ; Cc1cc2oc(C3=[N+]4C(=C(c5c(Cl)cncc5Cl)c5ccc(-c6cc7sc(C)cc7o6)n5[B-]4(F)F)C=C3)cc2s1]

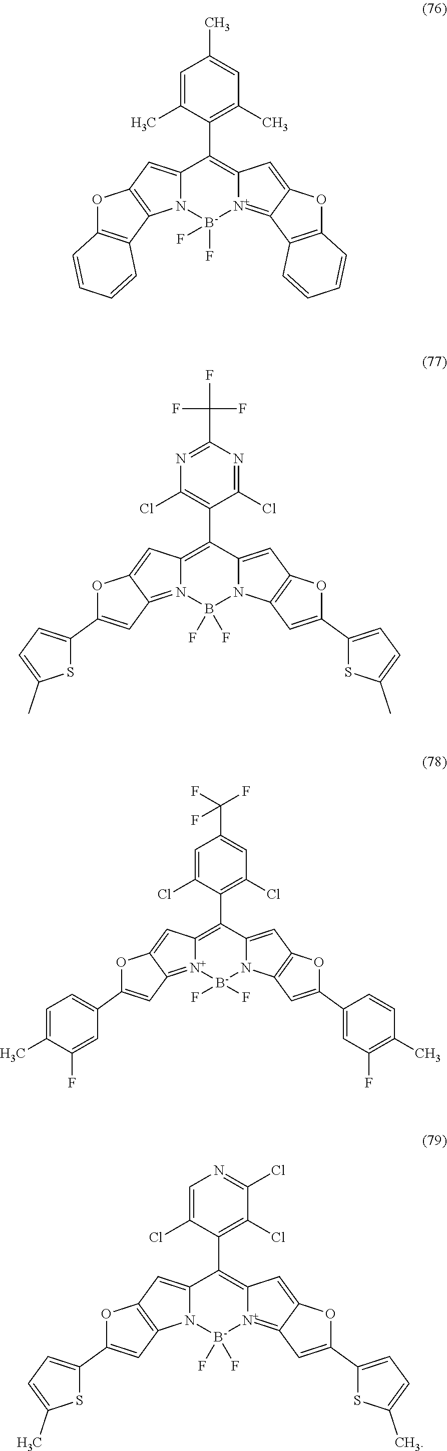

14. The use of at least one compound as claimed in any of claims 1 to 13 in a photoactive layer formed as a planar heterojunction (PHJ) in an optoelectronic component, preferably an organic optoelectronic component, wherein the organic optoelectronic component is preferably an organic photovoltaic element, an OLED, an OFET, or an organic photodetector.

15. A chemical compound of the general formula II 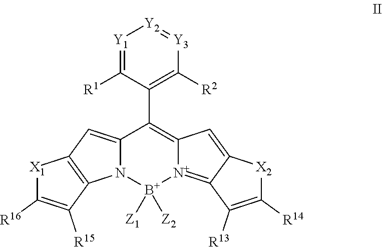
with Y₁ selected from the group consisting of N and CR21, wherein R21 is H, alkyl, O-alkyl, S-alkyl, a halogen, preferably F or Cl, CN or CF₃;
with Y₂ selected from the group consisting of N and CR22, wherein R22 is H, alkyl, O-alkyl, S-alkyl, a halogen, preferably F or Cl, CN or CF₃;
with Y₃ selected from the group consisting of N and CR23, wherein R23 is H, alkyl, O-alkyl, S-alkyl, a halogen, preferably F or Cl, CN or CF₃;
with Z₁ and Z₂ F or CF₃;
with X₁ and X₂ independently O, S or N—R8 with R8 selected from the group consisting of H, alkyl and aryl, wherein preferably X₁ and X₂ are S or X₁ and X₂ are O;
with R1 and R2 independently selected from the group consisting of H, F, Cl, Br, CN, CF₃, CHF₂, CH₂F, C1-C4-alkyl, O—C1-C4-alkyl, S—C1-C4-alkyl, and N—(C1-C4-alkyl)₂, with the proviso that at least R1 or R2 is Br, Cl, CF₃, CHF₂, CH₂F or CH₃;
wherein R13 and R15 are independently selected from the group consisting of H, halogen, CN, alkyl, O-alkyl and S-alkyl, preferably H or C1-C4-alkyl;
wherein R14 and R16 are independently selected from the group consisting of an unsubstituted and halogen-, alkyl-, fluorinated alkyl-, O-alkyl- and/or fluorinated O-alkyl-substituted heterocyclic 5-membered ring or 6-membered ring, preferably having a heteroatom independently selected from S, O and N, and an unsubstituted and halogen-, alkyl-, fluorinated alkyl-, O-alkyl- and/or fluorinated O-alkyl-substituted homocyclic 6-membered ring, preferably from an unsubstituted and substituted heterocyclic 5-membered ring, and an unsubstituted and substituted homocyclic 6-membered ring.
